(19) United States
(12) Patent Application Publication
(10) Pub. No.: US 2026/0206548 A1
(43) Pub. Date: Jul. 16, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Yu-Chi CHANG, Hsinchu (TW); Hsin-Li CHENG, Hsinchu (TW); Shu-Hui SU, Tucheng City (TW); Hai-Dang TRINH, Hsinchu (TW); Cheng-Tai HSIAO, Tainan City (TW); Yi-Yang WEI, Hsinchu (TW); Li-Feng TENG, Hsinchu City (TW); YingKit Felix TSUI, Cupertino, CA (US); Shih-Fen HUANG, Jhubei (TW)

(21) Appl. No.: 19/175,649

(22) Filed: Apr. 10, 2025

Related U.S. Application Data
(60) Provisional application No. 63/745,062, filed on Jan. 14, 2025.

(51) Int. Cl. H01L 21/66; H01L 21/48; H01L 23/00; H01L 23/498; H01L 23/538; H01L 25/18; H10B 80/00; H10D 80/30

(52) U.S. Cl. CPC H10P 74/273; H10W 70/093; H10W 70/611; H10W 70/65; H10W 70/66; H10W 70/685; H10W 90/00; H10B 80/00; H10D 80/30; H10W 72/019; H10W 72/01938; H10W 80/312; H10W 80/327; H10W 90/20; H10W 90/297; H10W 90/792

(57) ABSTRACT

Sacrificial test pads are formed in a semiconductor device and used for testing operations prior to bonding the semiconductor device with another semiconductor device to form a stacked semiconductor device. The sacrificial test pads may be formed in the interconnect layer, and may be formed of materials that enable the sacrificial test pads to be integrated into the manufacturing processes for the metallization of the interconnect layer. To prevent or reduce the likelihood of the uneven topographies of the sacrificial test pads from degrading bonding performance of the semiconductor devices, a planarization operation may be performed to planarize the surfaces of the sacrificial test pads. The sacrificial test pads may be subsequently covered by a dielectric layer to reduce the likelihood of oxidation of the sacrificial test pads. Retaining the sacrificial test pads, in turn, reduces the likelihood of oxidation of metallization structures under the sacrificial test pads.

### CROSS-REFERENCE TO RELATED APPLICATION

This Patent Application claims priority to U.S. Provisional Patent Application No. 63/745,062, filed on Jan. 14, 2025, and entitled “SEMICONDUCTOR DEVICE AND METHODS OF FORMATION.” The disclosure of the prior Application is considered part of and is incorporated by reference into this Patent Application.

### BACKGROUND

Various semiconductor device packing techniques may be used to incorporate one or more semiconductor dies into a semiconductor package. In some cases, semiconductor devices may be stacked in a semiconductor package to achieve a smaller horizontal or lateral footprint of the semiconductor package and/or to increase the density of the semiconductor package. Semiconductor device packing techniques that may be performed in order to integrate a plurality of semiconductor devices in a semiconductor package may include integrated fanout (InFO), package on package (PoP), chip on wafer (CoW), wafer on wafer (WoW), and/or chip on wafer on substrate (CoWoS), among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of an example stacked semiconductor device described herein.

FIGS. 2A and 2B are diagrams of an example implementation of a test pad that may be included in a semiconductor device described herein.

FIG. 3 is a diagram of an example implementation of a test pad that may be included in a semiconductor device described herein.

FIGS. 4A and 4B are diagrams of an example implementation of a test pad that may be included in a semiconductor device described herein.

FIGS. 5A and 5B are diagrams of an example implementation of a test pad that may be included in a semiconductor device described herein.

FIG. 6 is a diagram of an example implementation of a process for forming stacked semiconductor devices described herein.

FIGS. 7A-7P are diagrams of an example implementation of forming a semiconductor device described herein.

FIGS. 8A and 8B are diagrams of an example implementation of forming a stacked semiconductor device described herein.

FIG. 9 is a flowchart of an example process associated with forming a semiconductor device described herein.

FIG. 10 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a stacked semiconductor device, semiconductor devices may be directly bonded by WoW bonding such that the semiconductor devices are stacked and vertically arranged in the stacked semiconductor device. The use of direct bonding and vertical stacking of semiconductor devices may reduce interconnect lengths between the semiconductor devices (which reduces power loss and signal propagation times) and may enable increased density of semiconductor devices in a semiconductor package that includes the semiconductor devices.

Conductive test pads (e.g., metal test pads) may be formed on a semiconductor device to enable testing operations to be performed for the semiconductor die. Testing operations may be performed to test and/or verify proper operation of various aspects of the semiconductor die, and may include chip probe (CP) testing, wafer acceptance testing (WAT), and/or enhanced voltage stress (EVS) testing, among other examples. The testing operations may confirm whether circuits are operational, but only after the semiconductor device is bonded with another semiconductor device to form a semiconductor package. Thus, if one of the semiconductor dies does not pass the testing operations, both of the semiconductor dies in the semiconductor package are scrapped. This may result in the scrapping of semiconductor dies that do pass the testing operations, which reduces semiconductor device yield.

In some implementations described herein, sacrificial test pads are formed in a semiconductor device and used for testing operations for the semiconductor device prior to bonding the semiconductor device with another semiconductor device to form a stacked semiconductor device. The sacrificial test pads may be formed in the interconnect layer (e.g., the back end of the semiconductor device), and may be formed of materials such as copper (Cu) that enable the sacrificial test pads to be integrated into the manufacturing processes for the metallization of the interconnect layer.

The application of test probes to the sacrificial test pads may form marks, recesses, divots, and/or other imperfections in the sacrificial test pads, which may adversely affect wafer bonding when the semiconductor devices are being bonded together. To prevent or reduce the likelihood of the uneven topographies of the sacrificial test pads from degrading bonding performance of the semiconductor devices, a planarization operation may be performed to planarize the surfaces of the sacrificial test pads. The sacrificial test pads may be subsequently covered by a dielectric layer to reduce the likelihood of oxidation of the sacrificial test pads. Retaining the sacrificial test pads, in turn, reduces the likelihood of oxidation of metallization structures under the sacrificial test pads.

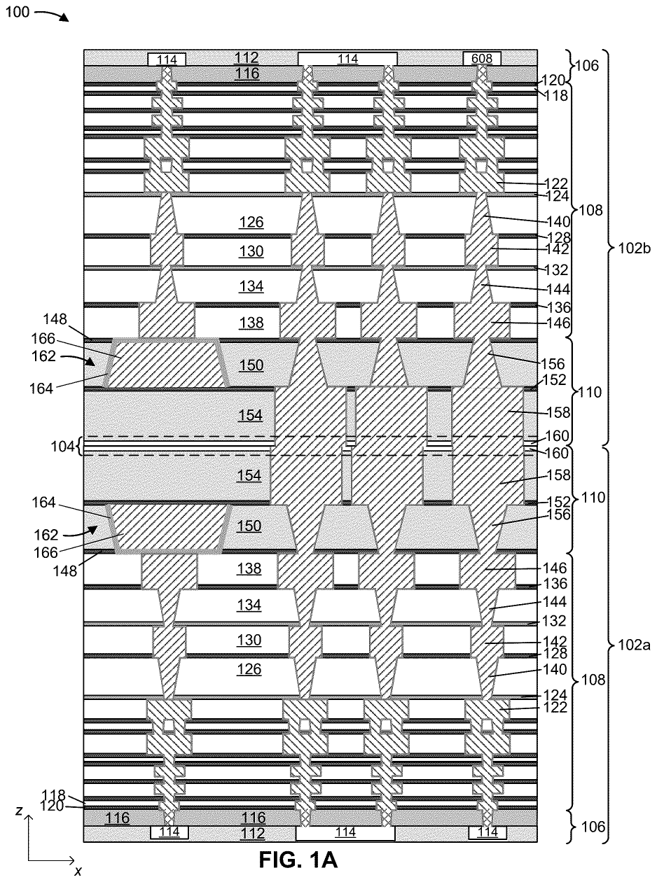

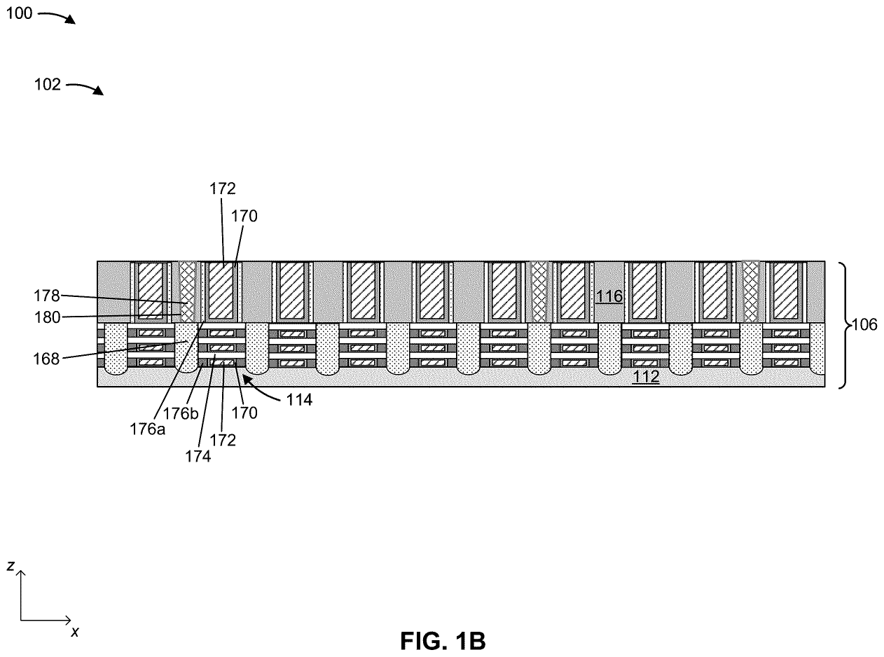

FIGS. 1A and 1B are diagrams of an example stacked semiconductor device 100 described herein. As shown in a cross-section view of the stacked semiconductor device 100 in FIG. 1A, the stacked semiconductor device 100 is a three-dimensional (3D) structure that includes a semiconductor device 102a and a semiconductor device 102b that are directly bonded together at a bonding interface 104 such that the semiconductor device 102a and the semiconductor device 102b are stacked and vertically arranged in the stacked semiconductor device 100. Thus, the stacked semiconductor device 100 includes a plurality of semiconductor devices that extend in an x-direction and/or in a y-direction, and that are arranged in a z-direction.

The semiconductor devices 102a and 102b may each include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the stacked semiconductor device 100 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. In general, the semiconductor device 102 is a semiconductor device that includes one or more capacitor structures in an interconnect layer of the semiconductor device 102.

In some implementations, semiconductor devices 102a and 102b are different types of semiconductor devices. For example, the semiconductor device 102a may include an SoC die, and the semiconductor device 102b may include an HBM die. As another example, the semiconductor device 102a may include an image sensor die, and the semiconductor device 102b may include an ASIC (e.g., an image processing) die.

In some implementations, the semiconductor devices 102a and 102b combine together to form functional regions of the stacked semiconductor device 100 that are distributed across the semiconductor devices 102a and 102b. For example, the stacked semiconductor device 100 may include a logic region that is distributed across the semiconductor devices 102a and 102b, an input/output (I/O) region that is distributed across the semiconductor devices 102a and 102b, and/or a memory region that is distributed across the semiconductor devices 102a and 102b, among other examples.

As shown in FIG. 1A, the semiconductor device 102a may include a device layer 106, an interconnect layer 108 vertically arranged (e.g., in a z-direction) in the semiconductor device 102a with the device layer 106, and a bonding layer 110 vertically arranged (e.g., in a z-direction) in the semiconductor device 102a with the interconnect layer 108.

The device layer 106 may also be referred to as a frontend region or a front end of line (FEOL) region of the semiconductor device 102a. The device layer 106 may include a substrate layer 112. The substrate layer 112 may correspond to a portion of a semiconductor wafer on which the semiconductor device 102a is formed. The substrate layer 112 may include a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 112 may extend in an x-direction and/or in a y-direction in the semiconductor device 102a.

Integrated circuit devices 114 may be included in and/or on the substrate layer 112 in the device layer 106 of the semiconductor device 102a. The integrated circuit devices 114 may include frontend transistor structures (e.g., frontend planar transistor structures, frontend fin field effect transistor (finFET) structures, frontend gate all around (GAA) transistor structures), pixel sensors, frontend capacitors, frontend resistors, frontend inductors, photodetectors, transceivers, transmitters, receives, optical circuits, and/or other types of frontend semiconductor devices. “Frontend semiconductor devices” refers to the semiconductor devices that are formed in the device layer 106 (e.g., in and/or on the substrate layer 112) of the semiconductor device 102a, as opposed to in the interconnect layer 108 of the semiconductor device 102a.

A dielectric layer 116 is included over the substrate layer 112. The dielectric layer 116 includes an interlayer dielectric (ILD) layer, an etch stop layer (ESL), and/or another type of dielectric layer. The dielectric layer 116 includes dielectric material(s) that enable various portions of the substrate layer 112 and/or the integrated circuit devices 114 to be selectively etched or protected from etching, and/or to electrically isolate the integrated circuit devices 114 in the device layer 106. The dielectric layer 116 includes a silicon nitride (SiₓN_{y}), an oxide (e.g., a silicon oxide (SiOₓ) and/or another oxide material), and/or another type of dielectric material. The dielectric layer 116 may extend in the x-direction and/or in a y-direction in the semiconductor device 102a.

The interconnect layer 108 of the semiconductor device 102a is included above the substrate layer 112 and above the integrated circuit devices 114 in the z-direction in the semiconductor device 102a. The integrated circuit devices 114 may be electrically coupled to the interconnect layer 108. The interconnect layer 108 includes a plurality of dielectric layers (e.g., backend dielectric layers) that are arranged in a direction (e.g., the z-direction) that is approximately perpendicular to the substrate layer 112. The dielectric layers may include ILD layers 118 and ESLs 120 that are arranged in an alternating manner in the z-direction. The ILD layers 118 and the ESLs 120 may extend in the x-direction and/or in the y-direction in the semiconductor device 102a.

The ILD layers 118 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 118 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 120 may each include a silicon nitride (SiₓN_{y}), silicon carbide (SiC), silicon oxynitride (SiON), and/or another suitable dielectric material. In some implementations, an ILD layer 118 and an ESL 120 include different dielectric materials to provide etch selectivity to enable various structures to be formed in the interconnect layer 108.

The interconnect layer 108 includes a plurality of conductive structures. One or more of the conductive structures 122 are electrically coupled and/or physically coupled to one or more of the integrated circuit devices 114 in the device layer 106. The conductive structures 122 provide electrical routing that enables signals and/or power to be provided to and/or from the integrated circuit devices 114. The conductive structures 122 may include a combination of metallization structures and interconnect structures. The metallization structures may include trenches, metallization layers, conductive traces, and/or other types of metallization structures. The interconnect structures may include vias, plugs, interconnects, and/or another type of interconnect structures. The conductive structures 122 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included on the conductive structures 122. The one or more liner layers may include barrier liners, adhesion liners, and/or another type of liners. Examples of materials for the one or more liners include tantalum nitride (TaN) and/or titanium nitride (TiN), among other examples.

In some implementations, the conductive structures 122 may be arranged in a plurality of layers that are arranged in a vertical manner (e.g., in the z-direction) in the interconnect layer 108. In other words, a plurality of layers of conductive structures 122 extend above the device layer 106 in the interconnect layer 108 to facilitate electrical signals and/or power to be routed between the device layer 106 and the interconnect layer 108. The metallization structures may be arranged in metallization layers referred to as M-layers. For example, a metal-0 (M0) layer that includes a plurality of conductive structures 122 (e.g., metallization structures) may be located at the bottom of the interconnect layer 108 and may be directly coupled to the device layer 106 (e.g., with the integrated circuit devices 114 in the device layer 106). A via-1 (V1) layer that includes a plurality of conductive structures 122 (e.g., interconnect structures) may be included above the M0 layer. A metal-1 layer (M1) layer that includes a plurality of conductive structures 122 (e.g., metallization structures) may be located above the V1 layer in the interconnect layer 108, a via-2 (V2) layer that includes a plurality of conductive structures 122 (e.g., interconnect structures) may be included above the M1 layer, a metal-2 (M2) layer that includes a plurality of conductive structures 122 (e.g., metallization structures) may be located above the V2 layer, and so on.

One or more top metal layers may be included above the conductive structures 122 (e.g., the M-layers and the V-layers) in the interconnect layer 108. For example, the interconnect layer 108 may include an ESL 124, an ILD layer 126, an ESL 128, an ILD layer 130, an ESL 132, an ILD layer 134, an ESL 136, and an ILD layer 138, and may include a top via 140 (e.g., extending through the ESL 124 and the ILD layer 126), a top metal layer 142 (e.g., extending through the ESL 128 and the ILD layer 130), a top via 144 (e.g., extending through the ESL 132 and the ILD layer 134), and/or a top metal layer 146 (e.g., extending through the ESL 136 and/or the ILD layer 138), among other examples.

The top vias 140 and 144 may be physically larger (e.g., may be taller in the z-direction) than the interconnect structures of the conductive structures 122. Similarly, the top metal layers 142 and 146 may be physically larger (e.g., may be taller in the z-direction) than the metallization structures of the conductive structures 122. For example, the metallization structures of the conductive structures 122 may have sub-micron z-direction heights, whereas the top metal layers 142 and 146 may have z-direction heights of approximately 1 micron or greater. However, other z-direction heights for the metallization structures of the conductive structures 122 and for the top metal layers 142 and 146 are within the scope of the present disclosure.

The physically larger sizes of the top vias 140 and 144 and of the top metal layers 142 and 146 provide for lower sheet resistance and enable higher current signals to be handled at the top of the interconnect layer 108. The physically smaller sizes of the conductive structures 122 enable a higher density of conductive structures 122 to be included closer to the integrated circuit devices 114 in the device layer 106, which enables the integrated circuit devices 114 to be positioned closer together for higher integrated circuit device density in the device layer 106.

In some implementations, the ESLs 124, 128, 132, and 136 may include an alternating arrangement of materials. For example, the ESLs 124 and 132 may include silicon carbide (SiC), and the ESLs 128 and 136 may include a silicon nitride (SiₓN_{y} such as Si₃N₄). However, other combinations of materials for the ESLs 124, 128, 132, and 136 are within the scope of the present disclosure.

In some implementations, the ESL 124 may have a z-direction thickness that is included in a range of approximately 300 angstroms to approximately 800 angstroms. However, other values for the range are within the scope of the present disclosure. In some implementations, the ILD layer 126 may have a z-direction thickness that is included in a range of approximately 4000 angstroms to approximately 8000 angstroms. However, other values for the range are within the scope of the present disclosure. In some implementations, the ESL 128 may have a z-direction thickness that is included in a range of approximately 300 angstroms to approximately 700 angstroms. However, other values for the range are within the scope of the present disclosure. In some implementations, the ILD layer 130 may have a z-direction thickness that is included in a range of approximately 6000 angstroms to approximately 12000 angstroms. However, other values for the range are within the scope of the present disclosure. In some implementations, the ESL 132 may have a z-direction thickness that is included in a range of approximately 300 angstroms to approximately 800 angstroms. However, other values for the range are within the scope of the present disclosure. In some implementations, the ILD layer 134 may have a z-direction thickness that is included in a range of approximately 4000 angstroms to approximately 8000 angstroms. However, other values for the range are within the scope of the present disclosure. In some implementations, the ESL 136 may have a z-direction thickness that is included in a range of approximately 300 angstroms to approximately 700 angstroms. However, other values for the range are within the scope of the present disclosure. In some implementations, the ILD layer 138 may have a z-direction thickness that is included in a range of approximately 7000 angstroms to approximately 10000 angstroms. However, other values for the range are within the scope of the present disclosure.

The bonding layer 110 may be connected to the top metal layer 146 of the interconnect layer 108. The bonding layer 110 may include additional ESLs and dielectric layers, such as an ESL 148, a passivation layer 150, an ESL 152, and/or a dielectric layer 154, among other examples. Moreover, the bonding layer 110 may include bonding interconnects 156 (e.g., that extend through the ESL 148 and/or the passivation layer 150) and bonding pads 158 (e.g., that extend through the ESL 152 and/or the dielectric layer 154). The bonding interconnects 156 may be electrically connected and/or physically connected to the top metal layer 146, and the bonding pads 158 may be electrically connected and/or physically connected to the bonding interconnects 156.

The ESLs 148 and 152 may each include a silicon nitride (SiₓN_{y}), silicon carbide (SiC), silicon oxynitride (SiON), and/or another suitable dielectric material. The passivation layer 150 and the dielectric layer 154 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material.

In some implementations, the ESL 148 may have a z-direction thickness that is included in a range of approximately 500 angstroms to approximately 1000 angstroms. However, other values for the range are within the scope of the present disclosure. In some implementations, the passivation layer 150 may have a z-direction thickness that is included in a range of approximately 4000 angstroms to approximately 9000 angstroms. However, other values for the range are within the scope of the present disclosure. In some implementations, the ESL 152 may have a z-direction thickness that is included in a range of approximately 800 angstroms to approximately 1600 angstroms. However, other values for the range are within the scope of the present disclosure. In some implementations, the dielectric layer 154 may have a z-direction thickness that is included in a range of approximately 6000 angstroms to approximately 12000 angstroms. However, other values for the range are within the scope of the present disclosure.

The bonding interconnects 156 include conductive structures that are elongated primarily in the z-direction. The bonding interconnects 156 may electrically couple the top metal layer 146 to the bonding pads 158. The bonding pads 158 may include electrically conductive pads that are used for bonding the semiconductor device 102a to another semiconductor device to form a vertically stacked semiconductor package. The bonding interconnects 156 and bonding pads 158 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The bonding layer 110 further includes a bonding dielectric layer 160 around the bonding pads 158. The bonding dielectric layer 160 may also be used to bond the semiconductor device 102a to another semiconductor device to form a vertically stacked semiconductor package. Thus, the combination of the bonding pads 158 and the bonding dielectric layer 160 enables the semiconductor device 102a to be bonded to another semiconductor device in a metal-to-metal bond and in a dielectric-to-dielectric bond. The bonding dielectric layer 160 may include one or more dielectric materials such as a silicon nitride (SiₓN_{y}), silicon carbide (SiC), silicon oxynitride (SiON), and/or another suitable dielectric material. In some implementations, a z-direction thickness of the bonding dielectric layer 160 may be included in a range of approximately 500 angstroms to approximately 1000 angstroms. However, other values for the range are within the scope of the present disclosure.

As further shown in FIG. 1A, the semiconductor device 102a may include one or more test pads 162. The test pad(s) 162 may be included in the interconnect layer 108 and/or in the bonding layer 110. For example, the test pad(s) 162 may be included in the passivation layer 150 and/or in the ESL 148. Thus, the test pad(s) 162 may be included in the same layer as the bonding interconnects 156.

A test pad 162 may be included on and/or may be electrically coupled to the top metal layer 146. In some implementations, the conductive structures 122, the top vias 140, the top metal layer 142, the top vias 144, and/or the top metal layer 146 electrically couples the test pad(s) 162 to one or more integrated circuit devices 114.

The test pad(s) 162 may be used during manufacturing of the semiconductor device 102a. In particular, the test pad(s) 162 may be used to test various circuits, structures, and/or aspects of the semiconductor device 102a prior to bonding the semiconductor device 102a and the semiconductor device 102b to form the stacked semiconductor device 100. For example, the test pad(s) 162 may be used to test the integrated circuit devices 114, the conductive structures 122, the top vias 140, the top metal layer 142, the top vias 144, and/or the top metal layer 146 for discontinuities, for CP testing, for WAT, and/or for EVS testing, among other examples.

A test pad 162 may include a barrier layer 164 and a metal pad 166 on the barrier layer 164. The barrier layer 164 may be included on sidewalls and a bottom surface of the metal pad 166. Thus, the barrier layer 164 may be included between the metal pad 166 and the top metal layer 146.

The metal pad 166 may be formed of one or more metal materials that are compatible with processes used to form the interconnect layer 108 and/or the bonding layer 110, such as copper (Cu), tungsten (W), cobalt (Co), ruthenium (Ru), titanium (Ti), aluminum (Al), gold (Au), and/or a combination thereof, among other examples of electrically conductive materials. The barrier layer 164 may include tantalum (Ta), titanium (Ti), tantalum nitride (TaN), titanium nitride (TiN), and/or another suitable barrier material for minimizing material migration from the metal pad 166 into the surrounding dielectric layers.

As further shown in FIG. 1A, the semiconductor device 102b may include a similar combination and/or a similar arrangement of layers and/or structures as the semiconductor device 102a. In the stacked semiconductor device 100, the orientation of the semiconductor device 102b may be mirrored in the z-direction relative to the orientation of the semiconductor device 102a so that the bonding layers 110 of the semiconductor devices 102a and 102b are facing each other. This enables the bonding dielectric layers 160 of the semiconductor devices 102a and 102b to be bonded together at the bonding interface 104, and the bonding pads 158 of the semiconductor devices 102a and 102b to be bonded together at the bonding interface 104. The bonding dielectric layers 160 may be bonded together in dielectric-to-dielectric bonds, and the bonding pads 158 may be bonded together in metal-to-metal bonds.

As further shown in FIG. 1A, because of the mirrored orientations in the z-direction of the semiconductor devices 102a and 102b, the test pad(s) 162 of the semiconductor devices 102a and the test pad(s) 162 of the semiconductor devices 102b may be facing each other. The test pad(s) 162 of the semiconductor devices 102a may be separated in the z-direction from the test pad(s) 162 of the semiconductor devices 102b by ESLs 152, the dielectric layers 154, and/or the bonding dielectric layers 160. The area vertically between the test pad(s) 162 of the semiconductor devices 102a and the test pad(s) 162 of the semiconductor devices 102b may be free of bonding pads 158 and bonding interconnects 156.

FIG. 1B illustrates a detailed view of the device layer 106 of the semiconductor device 102. The integrated circuit devices 114 may include nanostructure transistors. Examples of nanostructure transistors include nanowire transistors, nanosheet transistors, gate-all-around (GAA) transistors, multi-bridge channel transistors, nanoribbon transistors, and/or other types of nanostructure transistor in which the gate of the nanostructure transistor wraps around two or more sides of the channel layer of the nanostructure transistor.

As shown in FIG. 1B, an integrated circuit device 114 may include a plurality of source/drain regions 168 that are grown and/or otherwise formed on and/or around portions of the substrate layer 112. “Source/drain region(s)” may refer to a source or a drain, individually or collectively, dependent upon the context. The source/drain regions 168 may be formed by epitaxially growing doped semiconductor regions and/or by another semiconductor process. In some implementations, the source/drain regions 168 are formed in recessed portions in the substrate layer 112. The recessed portions may be formed by strained source/drain (SSD) etching of the substrate layer 112 and/or another type etching operation. In some implementations, the source/drain regions 168 are formed in recesses that are formed in an alternating stack of channel layers and sacrificial layers (e.g., silicon germanium (SiGe)) layers.

An integrated circuit device 114 may further include a gate dielectric layer 170 between a gate structure 172 and channel layers 174 of the integrated circuit device 114. The channel layers 174 may extend between the source/drain regions 168 of the integrated circuit device 114, and gate dielectric layer 170 and the gate structure 172 may interface with and/or may wrap around two or more sides of the channel layers 174. In some implementations, the gate dielectric layer 170 and the gate structure 172 interfaces with and/or wraps around at least three sides of the channel layers 174. In some implementations, the gate dielectric layer 170 and the gate structure 172 interfaces with and/or wraps around all four sides of the channel layers 174. In these implementations, the integrated circuit device 114 may be referred to as a nanostructure transistor such as a GAA transistor.

The channel layers 174 may include nanoscale layers of semiconductor material, such as silicon (Si), silicon germanium (SiGe), and/or doped silicon, among other examples. The channel layers 174 may be formed from silicon nanosheets that are formed as part of a nanosheet stack above the substrate layer 112.

In some implementations, the gate dielectric layer 170 includes a low dielectric constant (low-k) dielectric material such as silicon oxide (SiOₓ). In some implementations, the gate dielectric layer 170 includes a high dielectric constant (high-k) dielectric material such as hafnium oxide (HfOₓ).

The gate structure 172 may be located laterally between the source/drain regions 168. In some implementations, the gate structure 172 is formed of a polysilicon material. In these implementations, the polysilicon material may be doped with one or more types of dopants (e.g., p-type dopants, n-type dopants) to tune a work function of the gate structure 172.

In some implementations, the gate structure 172 is formed of one or more metal materials (e.g., tungsten (W), titanium (Ti), cobalt (Co), and/or another metal). In these implementations, the gate structure 172 may include one or more work function metal layers (e.g., p-type metal layers, n-type metal layers) for tuning the work function of the gate structure 172. The work function metal layer(s) may be included between the gate dielectric layer 170 and the gate structure 172.

A p-type work function metal layer may include one or more p-type metals, such as tungsten (W), cobalt (Co), titanium nitride (TiN), tungsten nitride (WN), and/or another metal having a work function that is greater than approximately 4.7 electron volts (eV), among other examples. A p-type work function metal layer may be included to tune the work function of the gate structure 172 such that the work function is adjusted close to the valence band of the material of the channel layers 174.

An n-type work function metal layer may include one or more metal materials that tune or adjust the work function of the gate structure 172 near the conduction band of the material of the channel layers 174 of the semiconductor device 102. In some implementations, an n-type work function metal layer may include titanium aluminum (TiAl). In some implementations, an n-type work function metal layer includes titanium aluminum carbon (TiAlC). In some implementations, an n-type work function metal layer another aluminum-containing metal. In some implementations, another n-type metal material is included in an n-type work function metal layer.

Various spacers may be included in the integrated circuit devices 114. For example, sidewall spacers 176a may be included on the sidewalls of the gate structure 172 to provide electrical isolation for the gate structure 172, among other examples. In some implementations, the sidewall spacers 176a are in contact with the gate dielectric layer 170. In some implementations, the sidewall spacers 176a are in contact with the work function metal layer. The sidewall spacers 176a may include a silicon oxide (SiOₓ), a silicon nitride (SiₓN_{y}), a silicon oxycarbide (SiOC), a silicon oxycarbonitride (SiOCN), and/or another suitable material.

As another example, inner spacers 176b may be included laterally between the gate structure 172 and the source/drain regions 168 of an integrated circuit device 114. The inner spacer 176b may be included to reduce parasitic capacitance in the integrated circuit device 114 and to protect the source/drain regions 168 from being etched in a nanosheet release operation to remove sacrificial layers between the channel layers 174. The inner spacers 176b may include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonitride (SiOCN), and/or another dielectric material.

The source/drain regions 168 are electrically coupled and/or physically coupled to source/drain contact structures 178. The source/drain contact structures 178 may include contact vias, contact plugs, and/or another type of contact structures that electrically connect the source/drain regions 168 of the integrated circuit devices 114 with the interconnect layer 108 of the semiconductor device 102. The source/drain contact structures 178 include cobalt (Co), ruthenium (Ru), tungsten (W), molybdenum (Mo), copper (Cu), and/or another electrically conductive material or metal material. One or more liner layers 180 may be included on sidewalls of the source/drain contact structures 178. The liner layer(s) 180 may include a barrier layer that is included to prevent or minimize diffusion of materials from the source/drain contact structures 178 to the surrounding dielectric layers, an adhesion layer or glue layer that is included to promote adhesion between the source/drain contact structures 178 and the surrounding dielectric layers, and/or another type of liner. Examples of materials for the liner layer(s) 180 include titanium nitride (TiN), tantalum nitride (TaN), and/or another suitable liner material.

As indicated above, FIGS. 1A and 1B are provided as an example. Other examples may differ from what is described with regard to FIGS. 1A and 1B.

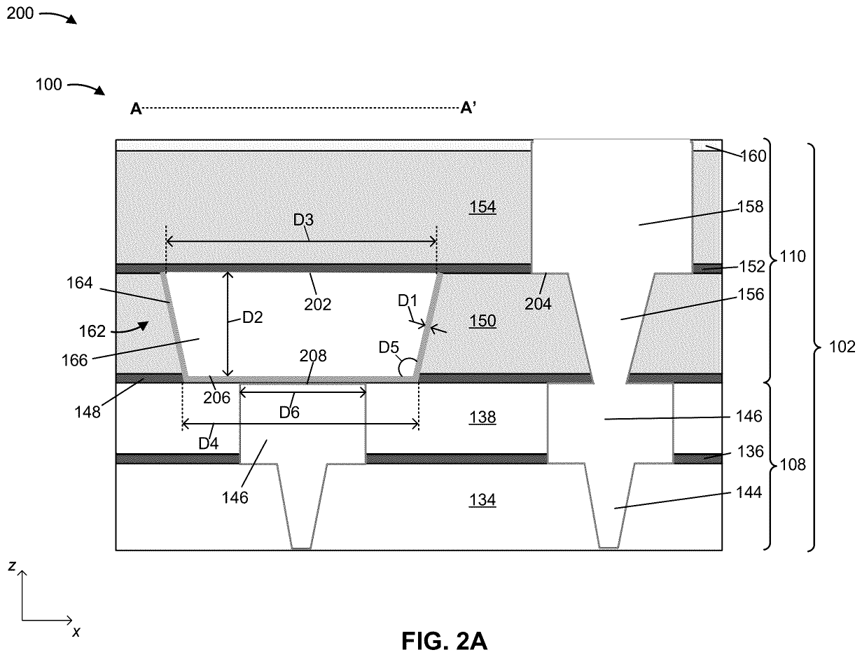

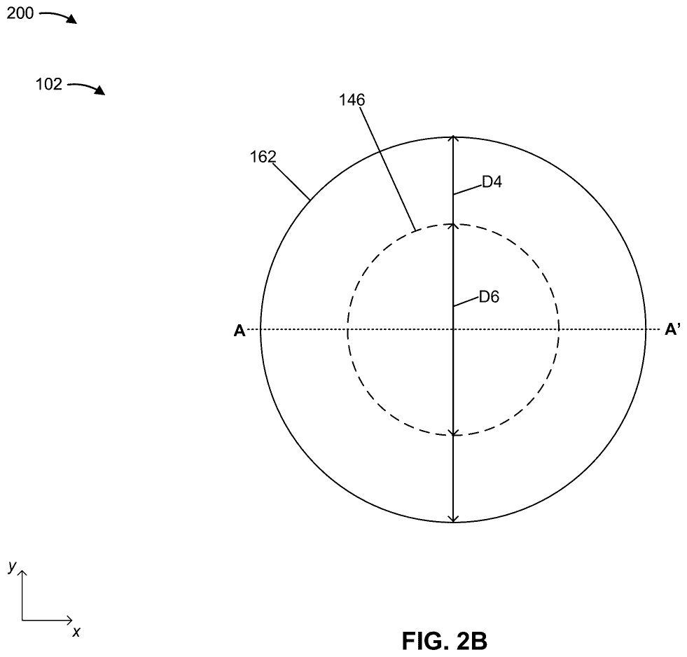

FIGS. 2A and 2B are diagrams of an example implementation 200 of a test pad 162 that may be included in a semiconductor device 102 described herein. The semiconductor device 102 may correspond to the semiconductor device 102a and/or the semiconductor device 102b of the stacked semiconductor device 100.

FIG. 2A illustrates a cross-section view of a portion of the semiconductor device 102. As shown in FIG. 2A, a top surface 202 of a test pad 162 of the semiconductor device 102 and a bottom surface 204 of a bonding pad 158 of the semiconductor device 102 may be approximately co-planar and at a same approximate height in the semiconductor device 102.

As further shown in FIG. 2A, the barrier layer 164 of the test pad 162 may have a thickness indicated in FIG. 2A as a dimension D1. In some implementations, the thickness of the barrier layer 164 is included in a range of approximately 1 angstrom to approximately 3 angstroms. If the thickness of the barrier layer 164 is less than approximately 1 angstrom, the thickness of the barrier layer 164 may be insufficient to effectively block diffusion of material from the metal pad 166 of the test pad 162 into the surrounding dielectric layers. If the thickness of the barrier layer 164 is greater than approximately 3 angstroms, the contact resistance between the metal pad 166 and the metallization structure of the top metal layer 146 under the test pad 162 may be high. If the thickness of the barrier layer 164 is included in the range of approximately 1 angstrom to approximately 3 angstroms, a low contact resistance may be achieved with low likelihood of material diffusion from the metal pad 166. However, other values, and ranges, other than approximately 1 angstrom to approximately 3 angstroms, are within the scope of the present disclosure.

As further shown in FIG. 2A, the metal pad 166 of the test pad 162 may have a thickness indicated in FIG. 2A as a dimension D2. In some implementations, the thickness of the metal pad 166 is included in a range of approximately 1 angstrom to approximately 10,000 angstroms to provide sufficient material to enable the metal pad 166 to be planarized multiple times to remove defects from testing, while being compatible with the heights of structures at the same level such as the bonding interconnects 156. However, other values and ranges are within the scope of the present disclosure.

As further shown in FIG. 2A, the test pad 162 may have a top width (indicated in FIG. 2A as a dimension D3) and a bottom width (indicated in FIG. 2A as a dimension D4). In some implementations, the top width is greater than the bottom width, resulting in angled or tapered sidewalls for the test pad 162. Thus, an angle between the bottom surface 206 of the test pad 162 and the sidewall of the test pad 162 (indicated in FIG. 2A as a dimension D5) may be greater than approximately 90 degrees and up to approximately 130 degrees, among other examples. However, other values and ranges are within the scope of the present disclosure. Alternatively, the angle between the bottom surface 206 of the test pad 162 and the sidewall of the test pad 162 (dimension D5) may be approximately 90 degrees, and the sidewalls may be substantially vertical such that the top width (dimension D3) and the bottom width (dimension D4) are approximately equal.

As further shown in FIG. 2A, and as shown in a top view in FIG. 2B, the bottom width (dimension D4) of the bottom surface 206 test pad 162 may be greater than the top width (dimension D6) of a top surface 208 of the metallization structure of the top metal layer 146 under the test pad 162. Thus, and as shown in the top view, the metallization structure of the top metal layer 146 under the test pad 162 may be located within the perimeter of the test pad 162. FIG. 2B further illustrates the location of the cross-section A-A′ of FIG. 2A.

As indicated above, FIGS. 2A and 2B are provided as an example. Other examples may differ from what is described with regard to FIGS. 2A and 2B.

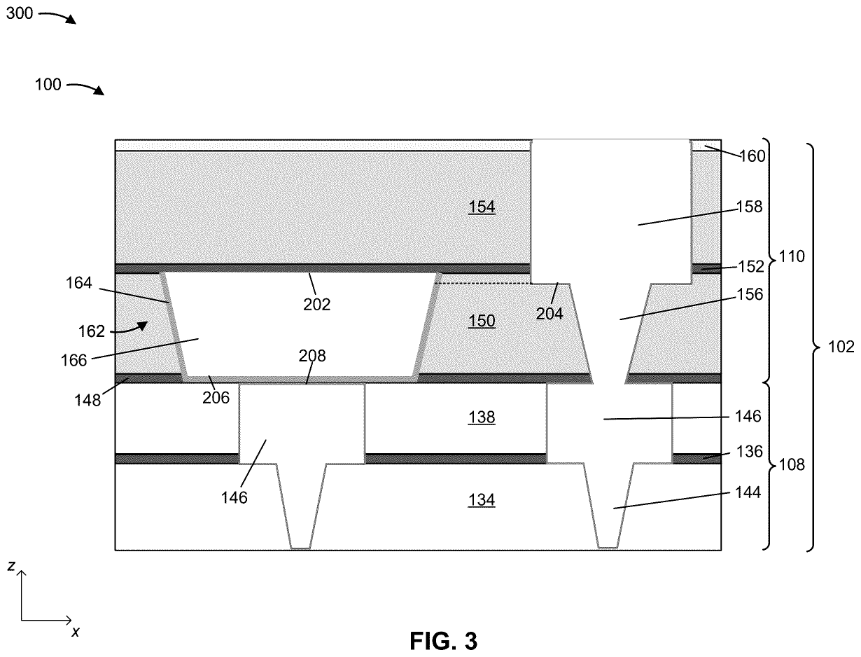

FIG. 3 is a diagram of an example implementation 300 of a test pad 162 that may be included in a semiconductor device 102 described herein. The semiconductor device 102 may correspond to the semiconductor device 102a and/or the semiconductor device 102b of the stacked semiconductor device 100.

As shown in FIG. 3, the example implementation 300 is similar to the example implementation 200 in FIG. 2A. However, in the example implementation 300, the top surface 202 of the test pad 162 is located at a higher vertical position in the semiconductor device 102 than the bottom surface 204 of a bonding pad 158 of the semiconductor device 102. This may occur where the recess in which the bonding pad 158 was formed extends into a portion of the passivation layer 150. This results in the bottom surface 204 of the bonding pad 158 being lower than the top surface 202 of the test pad 162, because the top surface 202 of the test pad 162 is approximately co-planar with the top surface of the passivation layer 150.

As indicated above, FIG. 3 is provided as an example. Other examples may differ from what is described with regard to FIG. 3.

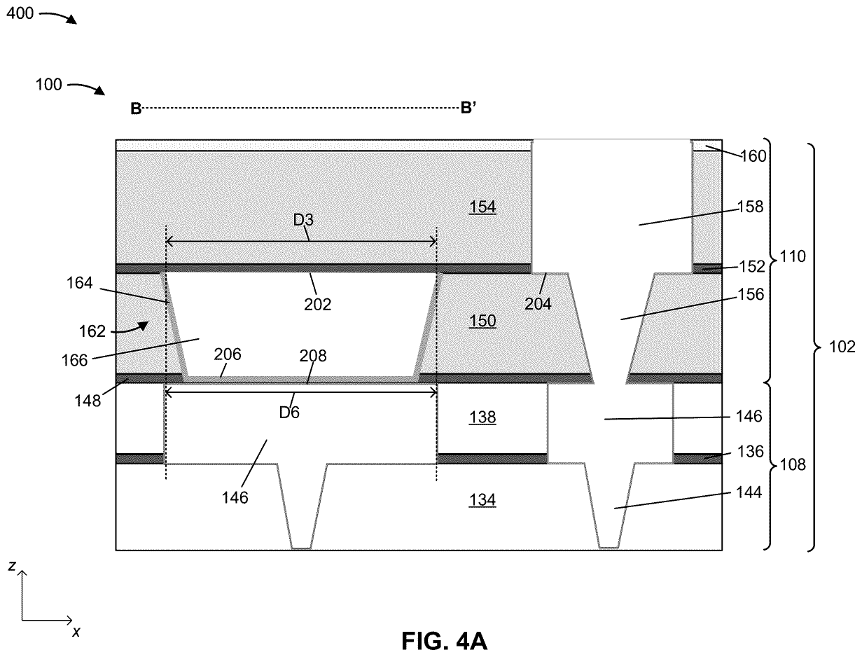

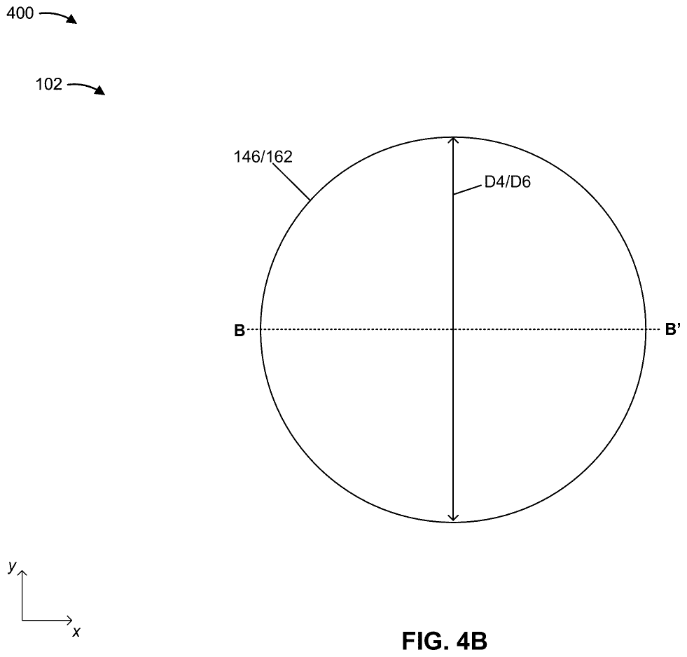

FIGS. 4A and 4B are diagrams of an example implementation 400 of a test pad 162 that may be included in a semiconductor device 102 described herein. The semiconductor device 102 may correspond to the semiconductor device 102a and/or the semiconductor device 102b of the stacked semiconductor device 100.

As shown in FIGS. 4A and 4B, the example implementation 400 is similar to the example implementation 200 in FIGS. 2A and 2B. However, in the example implementation 400, the top width of the top surface 202 of the test pad 162 (the dimension D3) and the top width of the top surface 208 of the metallization structure (the dimension D6) of the top metal layer 146 under the test pad 162 are approximately equal.

Additionally and/or alternatively, the bottom width of the bottom surface 206 of the test pad 162 (the dimension D4) and the top width of the top surface 208 of the metallization structure (the dimension D6) of the top metal layer 146 under the test pad 162 may be approximately equal.

As indicated above, FIGS. 4A and 4B are provided as an example. Other examples may differ from what is described with regard to FIGS. 4A and 4B.

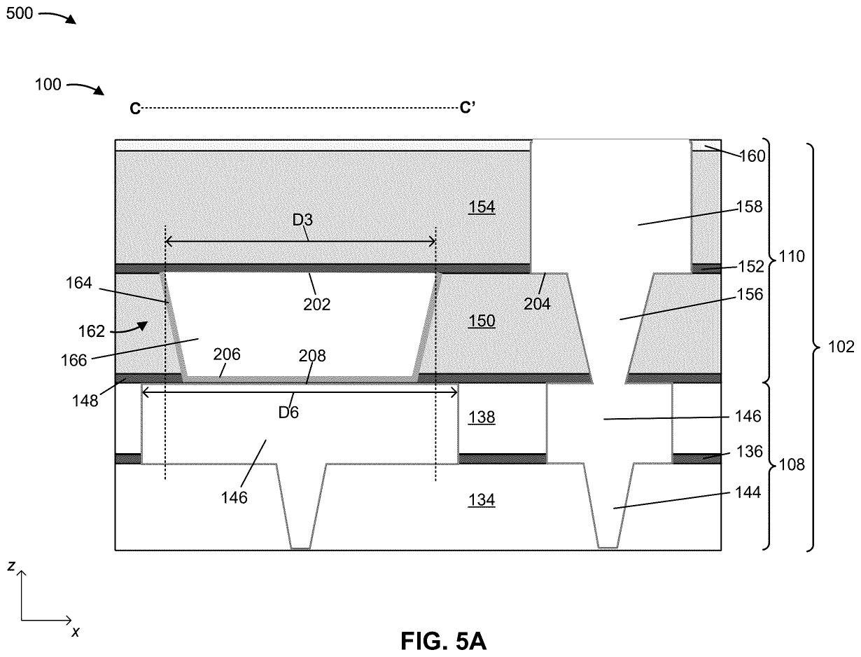

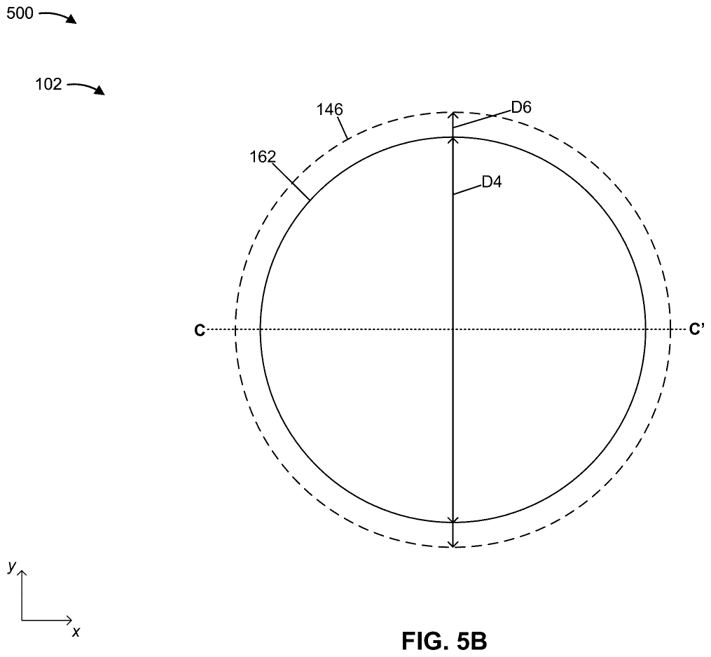

FIGS. 5A and 5B are diagrams of an example implementation 500 of a test pad 162 that may be included in a semiconductor device 102 described herein. The semiconductor device 102 may correspond to the semiconductor device 102a and/or the semiconductor device 102b of the stacked semiconductor device 100.

As shown in FIGS. 5A and 5B, the example implementation 500 is similar to the example implementation 200 in FIGS. 2A and 2B. However, in the example implementation 500, the top width of the top surface 202 of the test pad 162 (the dimension D3) may be less than the top width of the top surface 208 of the metallization structure (the dimension D6) of the top metal layer 146 under the test pad 162.

Additionally and/or alternatively, the bottom width of the bottom surface 206 of the test pad 162 (the dimension D4) may be less than the top width of the top surface 208 of the metallization structure (the dimension D6) of the top metal layer 146 under the test pad 162.

As indicated above, FIGS. 5A and 5B are provided as an example. Other examples may differ from what is described with regard to FIGS. 5A and 5B.

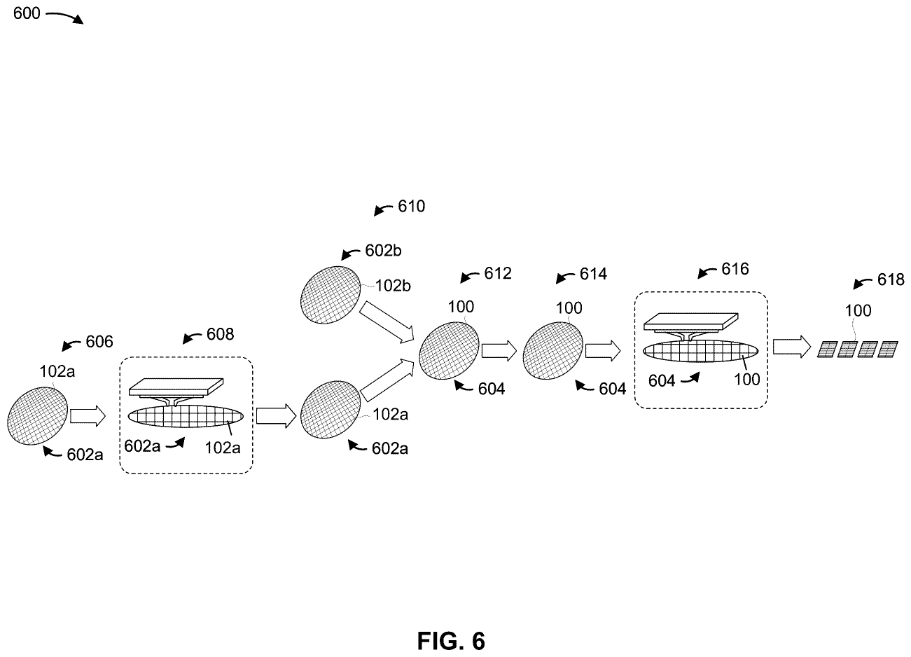

FIG. 6 is a diagram of an example implementation 600 of a process for forming stacked semiconductor devices 100 described herein. As shown in FIG. 6, forming the stacked semiconductor devices 100 may include forming semiconductor devices 102a on a semiconductor wafer 602a, forming semiconductor devices 102b on a semiconductor wafer 602b, and bonding the semiconductor wafers 602a and 602b together to form a wafer stack 604 that includes

[symbol]

At 606, portions of the semiconductor devices 102a may be formed on the semiconductor wafer 602a. Portions of the semiconductor devices 102b may similarly be formed on a semiconductor wafer 602b. Forming the portions of the semiconductor devices 102a (and/or forming the portions of the semiconductor devices 102b) at 606 may include forming test pad(s) 162 in the semiconductor devices 102a (and/or in the semiconductor devices 102b).

At 608, testing may be performed on the semiconductor devices 102a formed on the semiconductor wafer 602a at 608. Testing of the semiconductor devices 102a formed on the semiconductor wafer 602a may also be performed. Testing of the semiconductor devices 102a may include probing the semiconductor devices 102a using the test pad(s) 162 on the semiconductor devices 102a, and/or testing of the semiconductor devices 102a may include probing the semiconductor devices 102b using the test pad(s) 162 on the semiconductor devices 102b.

At 610, additional portions of the semiconductor devices 102a may be formed on the semiconductor wafer 602a, and additional portions of the semiconductor devices 102b may be formed on the semiconductor wafer 602b. The additional portions of the semiconductor devices 102a may be formed after the testing is performed on the semiconductor devices 102a, and/or the additional portions of the semiconductor devices 102b may be formed after the testing is performed on the semiconductor devices 102b.

At 612, the semiconductor wafers 602a and 602b may be bonded together to form the wafer stack 604 that includes the semiconductor wafers 602a and 602b. Bonding the semiconductor wafers 602a and 602b results in the semiconductor devices 102a on the semiconductor wafer 602a being bonded with semiconductor devices 102b on the semiconductor wafer 602b, which results in formation of stacked semiconductor devices 100.

At 614, additional portions of the stacked semiconductor devices 100 may be formed after the bonding operation. For example, backside processing may be performed to form backside structures and/or layers on the backsides of the stacked semiconductor devices 100.

At 616, additional testing may be performed on the stacked semiconductor devices 100. The additional testing may include a final CP test, a final WAT, and/or another type of test.

At 618, a die singulation tool may be used to cut or dice the wafer stack 604 into individual stacked semiconductor devices 100. The stacked semiconductor devices 100 may be packaged and/or shipped to another facility for further processing.

As indicated above, FIG. 6 is provided as an example. Other examples may differ from what is described with regard to FIG. 6.

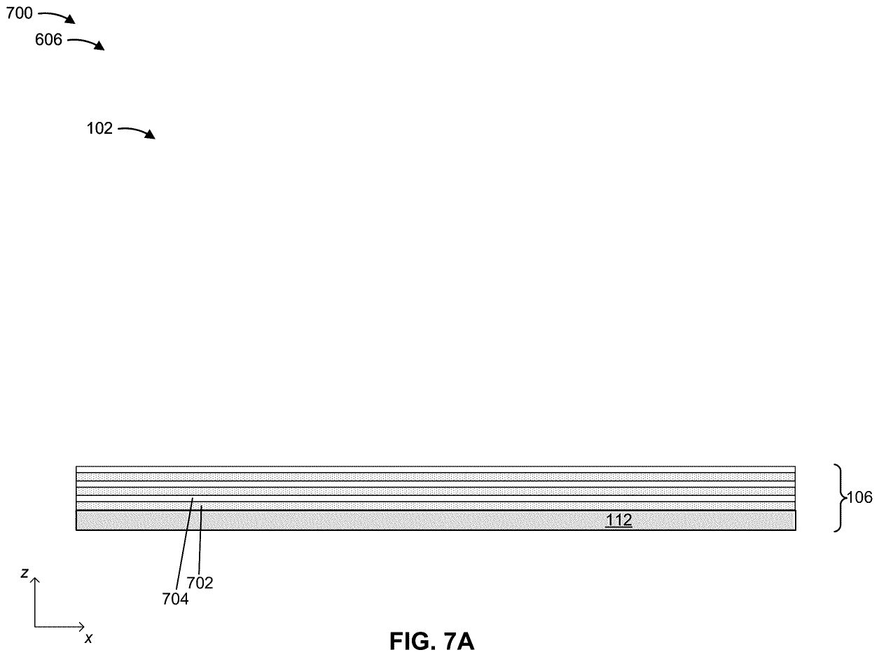

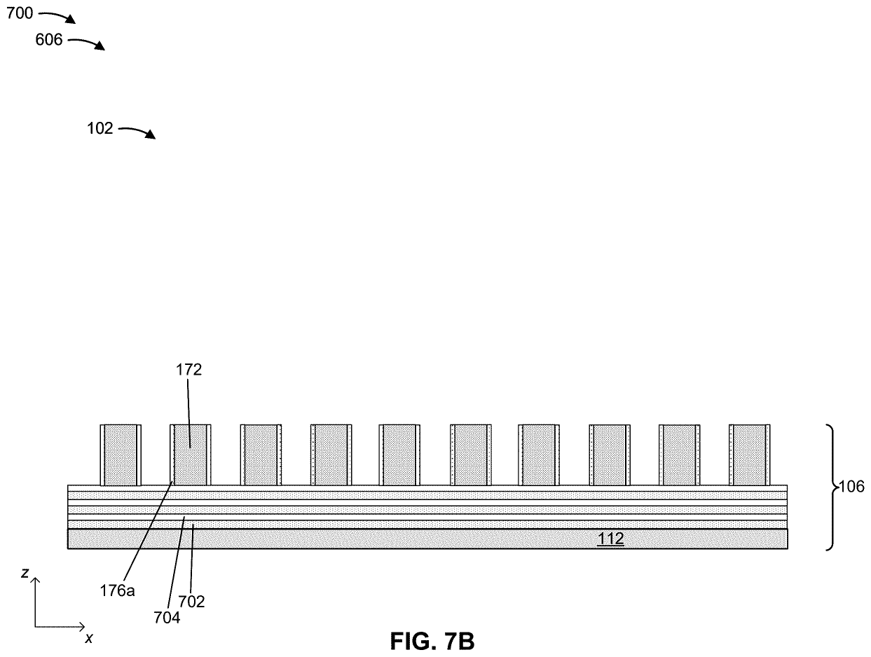

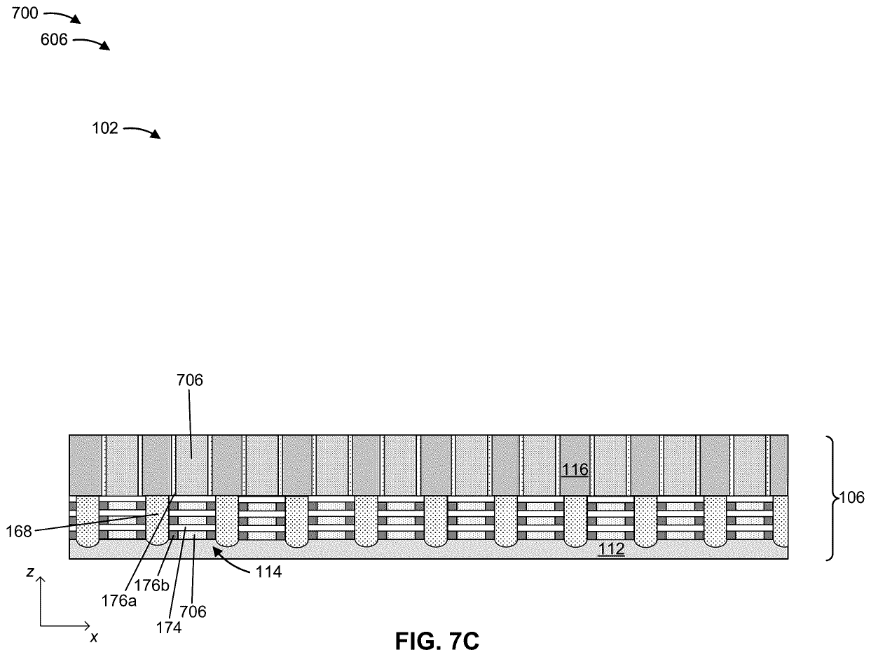

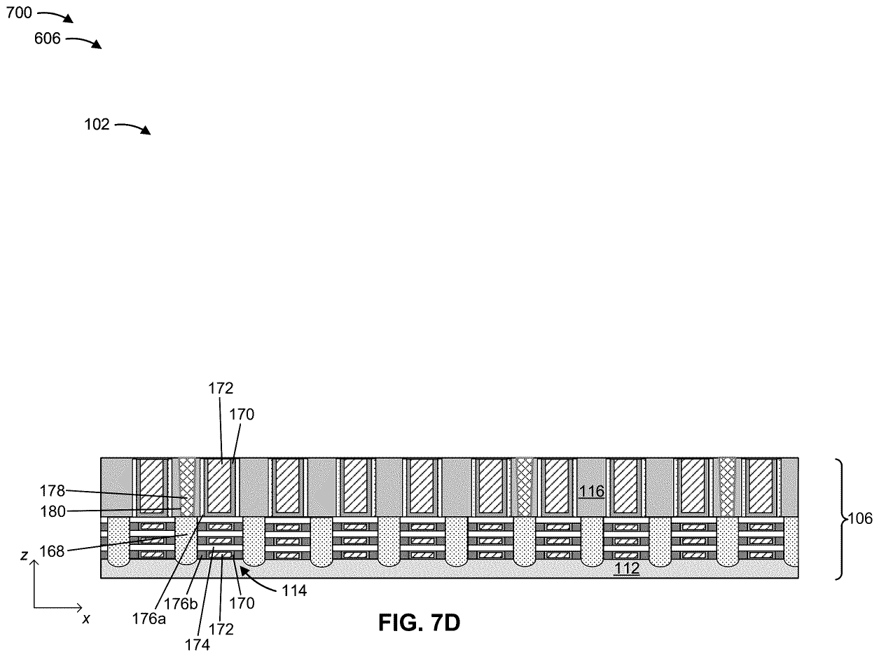

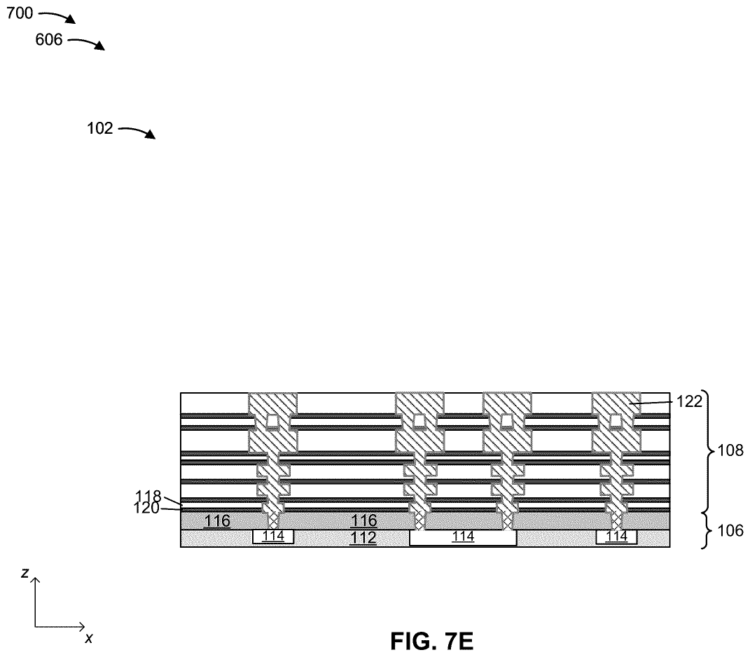

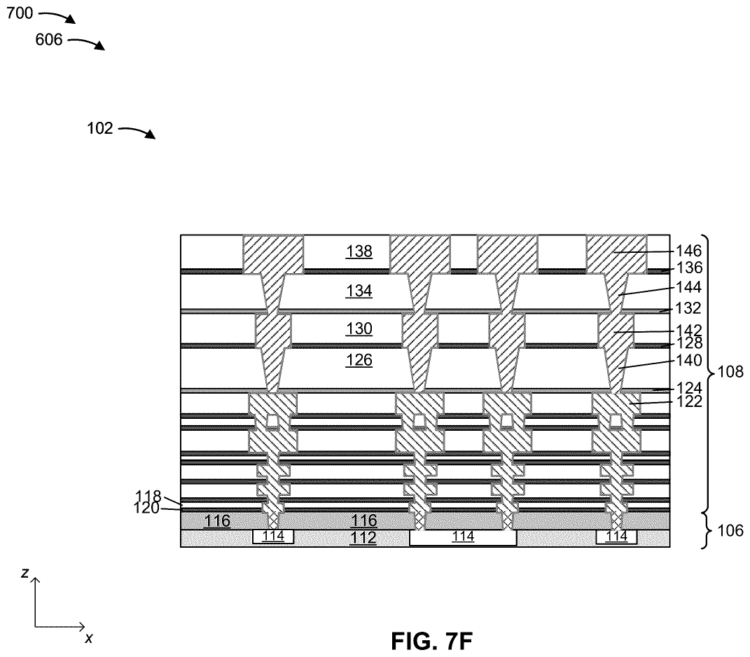

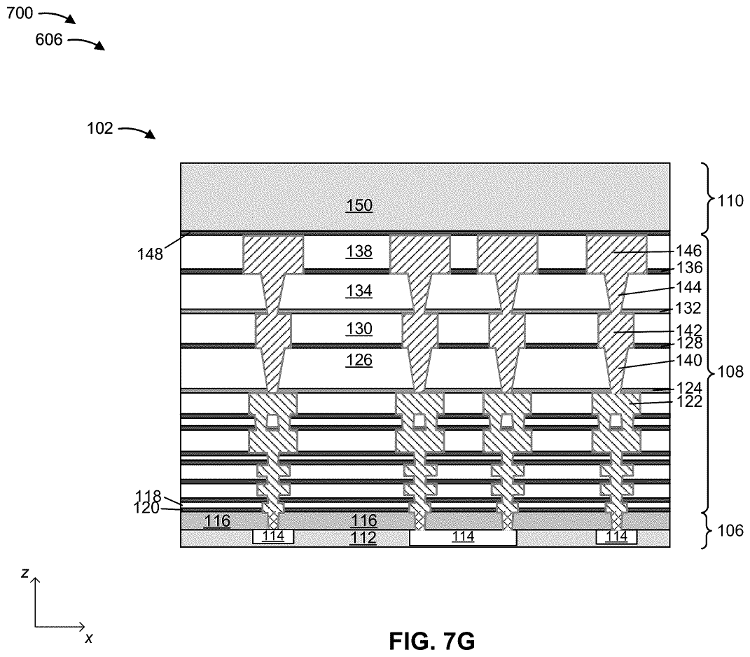

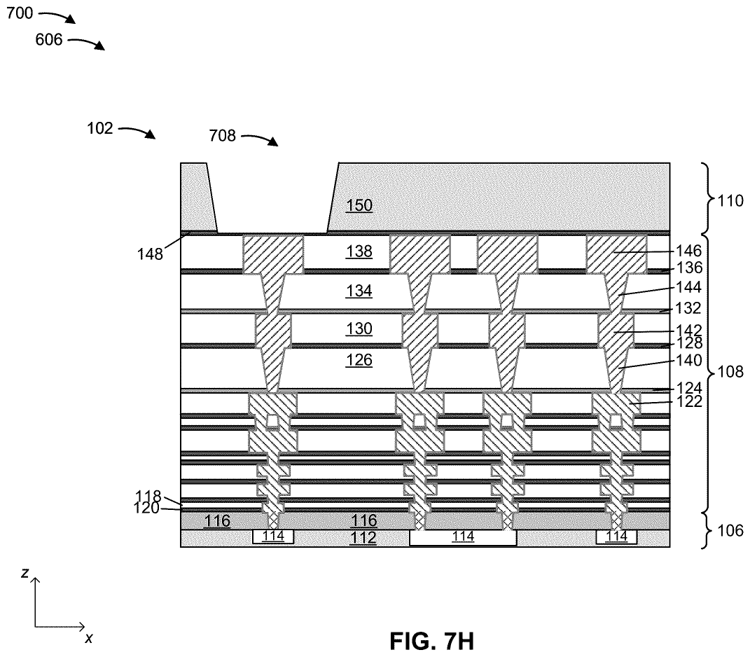

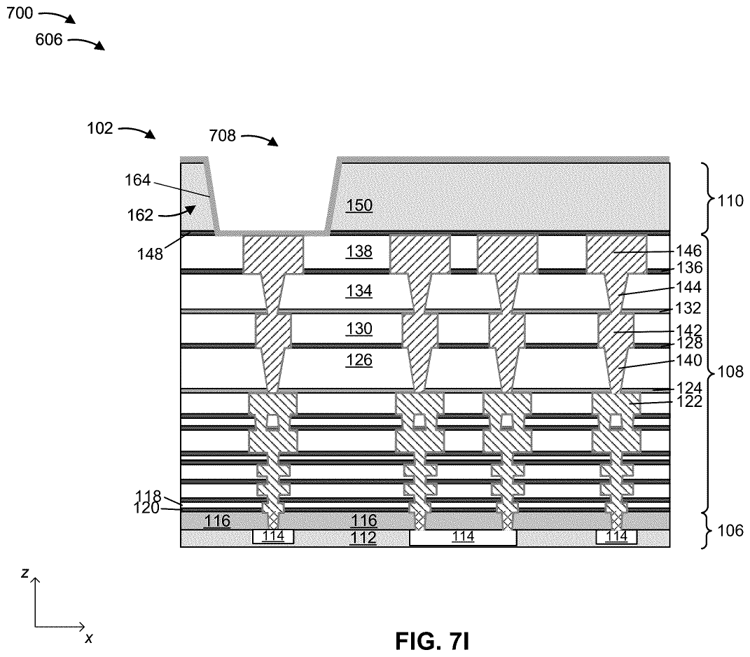

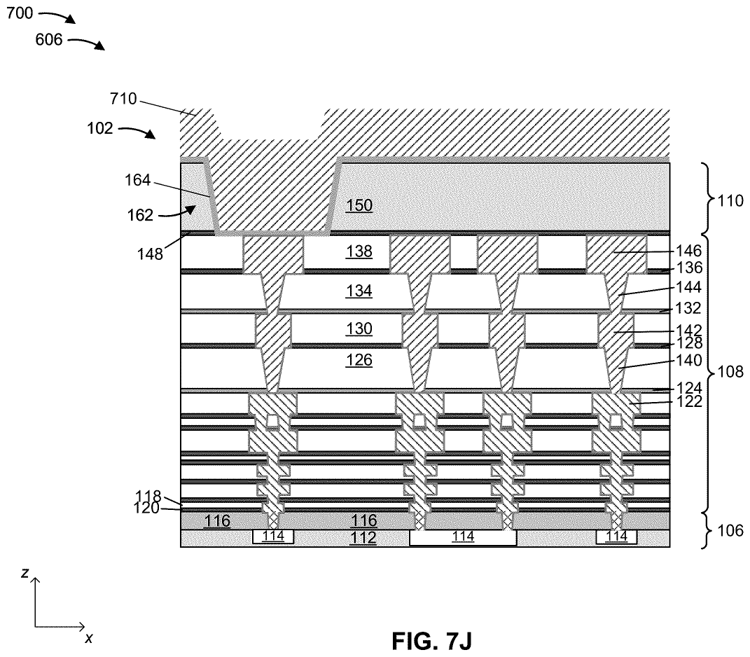

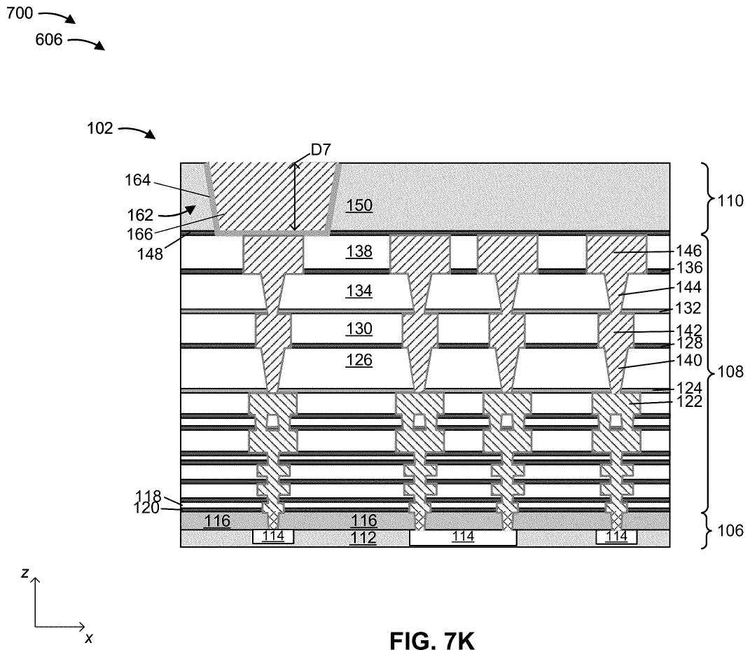

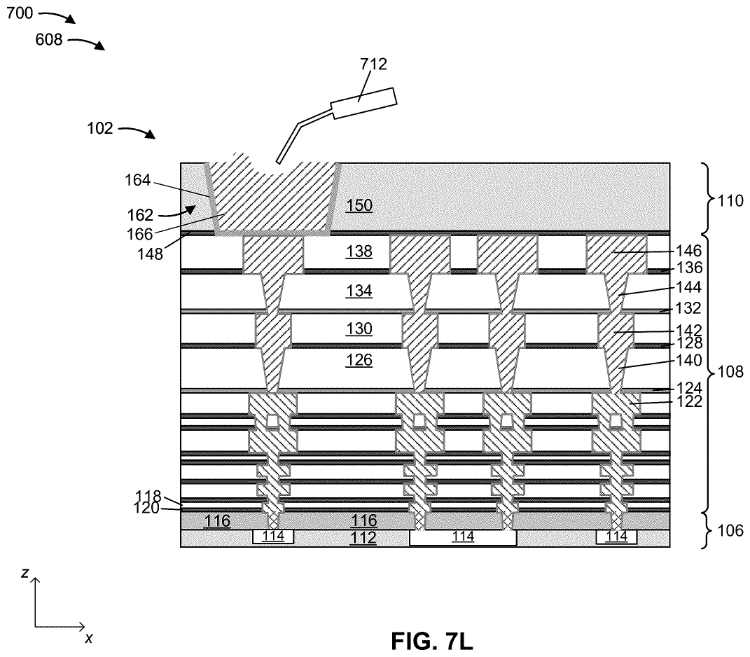

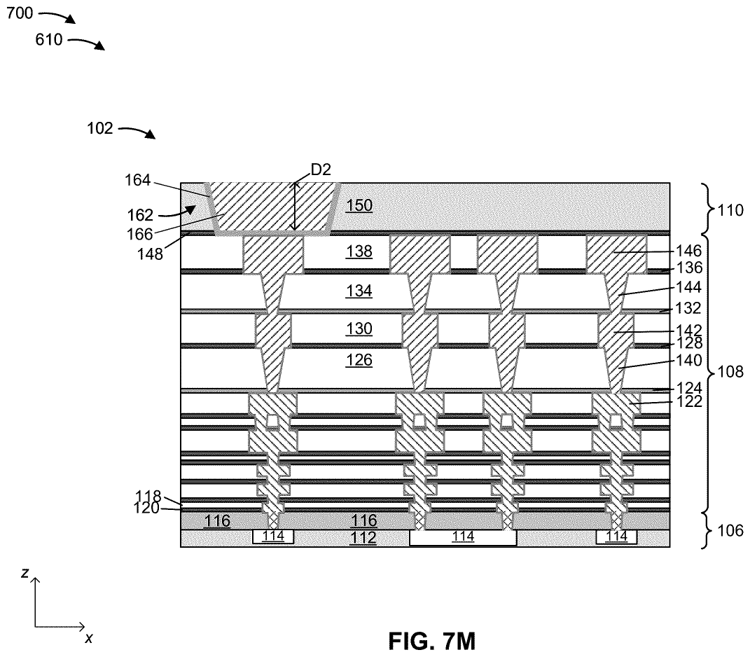

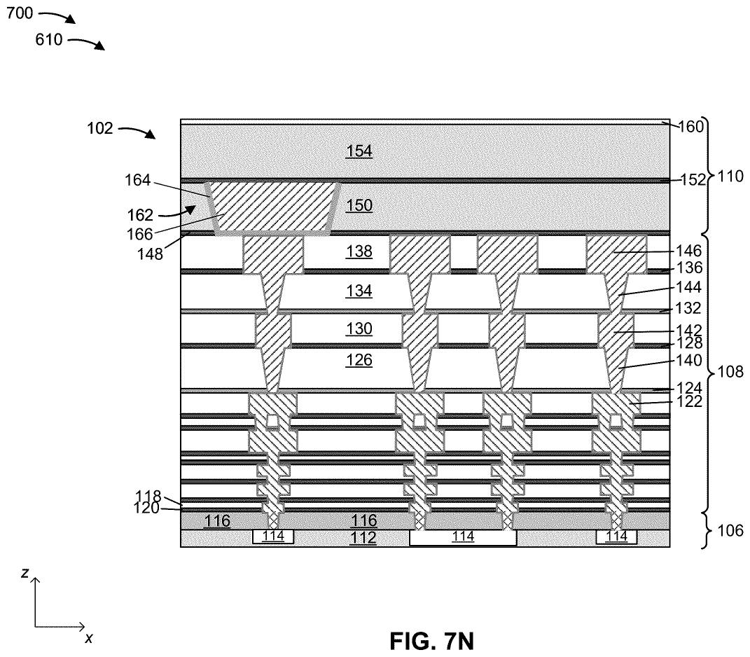

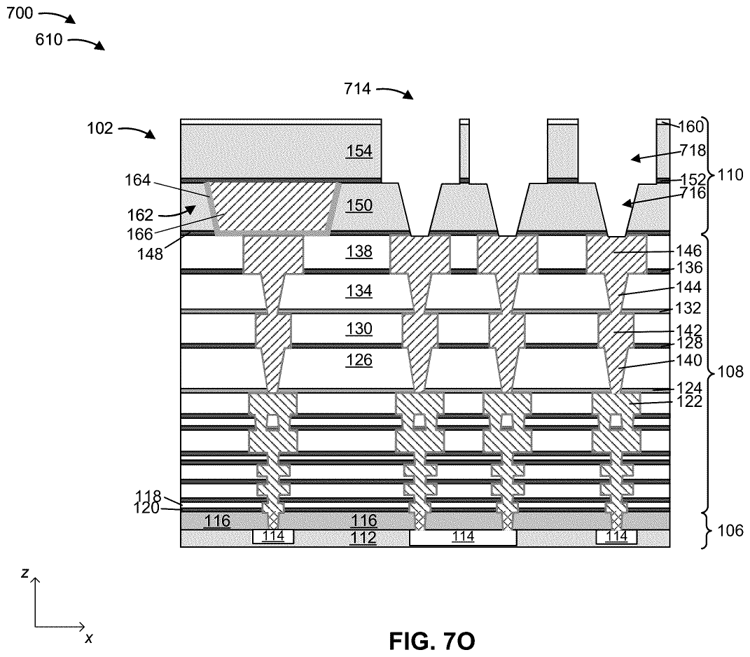

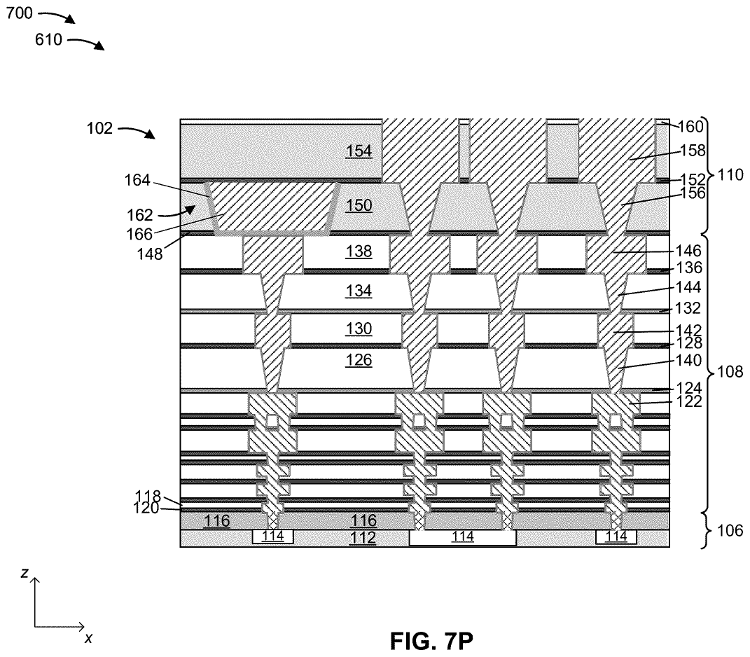

FIGS. 7A-7P are diagrams of an example implementation 700 of forming a semiconductor device 102 described herein. The semiconductor device 102 may include a semiconductor device 102a and/or a semiconductor device 102b that is to be bonded to another semiconductor device 102 to form a stacked semiconductor device 100. The example implementation 700 may include operations that are performed as part of the process illustrated in connection with FIG. 6, such as operations performed as part of 606, 608, and/or 610, among other examples. In some implementations, one or more semiconductor processing tools, such as a deposition tool, an exposure tool, a developer tool, an etch tool, an ion implantation tool, a planarization tool, and/or another type of semiconductor processing tool, may be used to perform one or more operations described in connection with FIGS. 7A-7P.

FIGS. 7A-7K illustrate operations that may be performed as part of 606 in FIG. 6. As shown in FIG. 7A, the substrate layer 112 is provided. The substrate layer 112 may be provided in the form of a semiconductor wafer (e.g., a semiconductor wafer 602a, a semiconductor 602b) such as a silicon (Si) wafer, a silicon-on-insulator (SOI) wafer, and/or another type of semiconductor work piece. The semiconductor device 102 may be formed on the semiconductor wafer with other semiconductor devices.

A layer stack may be formed on the substrate layer 112. The layer stack may be referred to as a superlattice. The layer stack may include a plurality of alternating layers that are arranged in a direction (e.g., the z-direction) that is approximately perpendicular to the substrate layer 112. For example, the layer stack may include vertically alternating layers of sacrificial layers 702 and nanostructure channel layers 704 above the substrate layer 112. The quantity of the sacrificial layers 702 and the quantity of the nanostructure channel layers 704 illustrated in FIG. 7A are examples, and other quantities of the sacrificial layers 702 and the nanostructure channel layers 704 are within the scope of the present disclosure.

The sacrificial layers 702 enable a vertical distance to be defined between adjacent nanostructure channels that are formed from the nanostructure channel layers 704, and serve as placeholder layers for subsequently-formed gate structures of the integrated circuit devices 114 of the semiconductor device 102 that are formed around the nanostructure channels.

The sacrificial layers 702 include a first material composition, and the nanostructure channel layers 704 include a second material composition. In some implementations, the first material composition and the second material composition are the same material composition. In some implementations, the first material composition and the second material composition are different material compositions. As an example, the sacrificial layers 702 may include silicon germanium (SiGe) and the nanostructure channel layers 704 may include silicon (Si). This enables the sacrificial layers 702 and/or the nanostructure channel layers 704 to be selectively etched (e.g., enables the sacrificial layers 702 and not the nanostructure channel layers 704 to be etched, enables the nanostructure channel layers 704 and not the sacrificial layers 702 to be etched) depending on the type of etchant that is used.

One or more types of deposition tools may be used to deposit and/or grow the alternating layers of the layer stack to include nanostructures (e.g., nanosheets) on the substrate layer 112. For example, a deposition tool may be used to grow the sacrificial layers 702 and/or the nanostructure channel layers 704 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial layers 702 and/or the nanostructure channel layers 704 may be deposited by chemical vapor deposition (CVD), physical vapor deposition (PVD), atomic layer deposition (ALD), and/or another suitable deposition technique.

In the y-direction, which is approximately perpendicular to the view illustrated in FIG. 7A, the layer stack and the substrate layer 112 may be etched to form fin structures that extend in the x-direction. A fin structure may include a portion of the layer stack and a portion of the substrate layer 112 under the layer stack. The fin structures may be formed by patterning the one or more masking layers and etching based on a pattern formed in one or more of the masking layers. The one or more masking layers may be patterned using photolithography techniques, including double-patterning or multi-patterning techniques. An etch tool may be used to etch the layer stack and the substrate layer 112 based on the pattern using a dry etch technique (e.g., reactive ion etching), a wet etch technique, and/or a combination thereof. In some implementations, shallow trench isolation (STI) regions (not shown) may be formed between adjacent fin structures in the y-direction.

As shown in FIG. 7B, dummy gate structures 706 (also referred to as dummy gate stacks or temporary gate structures) may be formed over portions of the layer stack of sacrificial layers 702 and nanostructure channel layers 704. The dummy gate structures 706 may extend in the y-direction and may be arranged in the x-direction such that the dummy gate structures 706 are approximately perpendicular to the fin structures. The dummy gate structures 706 are sacrificial structures that are to be replaced by replacement gate structures or replacement gate stacks at a subsequent processing stage for the integrated circuit devices 114 of the semiconductor device 102. The dummy gate structures 706 may also be used to define source/drain recesses in which source/drain regions of the nanostructure transistors are formed in the layer stack of sacrificial layers 702 and nanostructure channel layers 704.

The dummy gate structures 706 may include polycrystalline silicon (polysilicon or PO) or another material. The layers of the dummy gate structures 706 may be formed using various semiconductor processing techniques such depositing the layers of the dummy gate structures 706, patterning the layers of the dummy gate structures 706 to define the dummy gate structures 706, and/or other semiconductor processing techniques. The sidewall spacers 176a may be formed on the sidewalls of the dummy gate structures 706.

As shown in FIG. 7C, the source/drain regions 168 of the integrated circuit devices 114 are formed in the layer stack of sacrificial layers 702 and nanostructure channel layers 704. To form the source/drain regions 168, source/drain recesses may be formed through the layer stack of sacrificial layers 702 and nanostructure channel layers 704 in an etch operation. The source/drain recesses may be formed on opposing sides of a dummy gate structure 706 in the x-direction. The etch operation may be performed using the etch tool and may be referred to a strained source/drain (SSD) etch operation. In some implementations, the etch operation includes the use of a plasma etch technique, a wet chemical etch technique, and/or another type of etch technique.

Formation of the source/drain recesses may define the channel layers 174. The channel layers 174 may include silicon-based nanostructures (e.g., nanosheets or nanowires, among other examples) that function as the semiconductive channels of the integrated circuit devices 114 of the semiconductor device 102. The channel layers 174 are arranged in a direction (e.g., the z-direction) that is approximately perpendicular to the substrate layer 112. In other words, the channel layers 174 are vertically arranged or stacked above the substrate layer 112.

Prior to formation of the source/drain regions 168 in the source/drain recesses, the ends of the sacrificial layers 702 that are exposed in the source/drain recesses may be laterally etched in an etch operation, thereby forming cavities in the ends of the sacrificial layers 702. The inner spacers 176b may be formed in the cavities. To form the inner spacers 176b, a deposition tool may be used to deposit a layer of dielectric material in the cavities and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 176b in the cavities.

After formation of the inner spacers 176b, the source/drain recesses may be filled with one or more layers of epitaxial material to form the source/drain regions 168 in the source/drain recesses. For example, a deposition tool may be used to deposit a buffer region at the bottom of the source/drain recess, and a deposition tool may deposit a source/drain region 168 on the buffer region in the source/drain recess. In some implementations, a deposition tool is used to deposit a capping layer on the source/drain region 168 in the source/drain recess. As another example, a deposition tool may epitaxially grow a first layer of a source/drain region 168 (referred to as an L1) over an associated buffer region (which may be referred to as an L0), and may epitaxially grow a second layer of the source/drain region 168 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 102 and to reduce dopant extrusion or migration into the channel layers 174. The second layer may include a highly doped silicon or highly doped silicon germanium. The second layer may be included to provide a compressive stress in the source/drain regions 168 to reduce boron loss.

As further shown in FIG. 7C, the dielectric layer 116 may be formed over the source/drain regions 168 and around the dummy gate structures 706. The dielectric layer 116 may fill in areas between the dummy gate structures 706. In some implementations, a contact etch stop layer (CESL) is conformally deposited (e.g., by a deposition tool) over the source/drain regions 168 prior to formation of the dielectric layer 116. The dielectric layer 116 is then formed on the CESL. The CESL may provide a mechanism to stop an etch process when forming source/drain contact structures 178 for the source/drain regions 168. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As shown in FIG. 7D, a replacement gate process may be performed to replace the dummy gate structures 706 with the gate structures 172 of the integrated circuit devices 114. A dummy gate removal operation may be performed to remove the dummy gate structures 706 from the semiconductor device 102. The removal of the dummy gate structures 706 leaves behind openings (or recesses) in the dielectric layer 116, and provides access to the underlying sacrificial layers 702. The dummy gate structures 706 may be removed in one or more etch operations. Such etch operations may include a plasma etch technique, a wet chemical etch technique, and/or another type of etch technique.

The replacement gate process may include a nanostructure release operation (e.g., an SiGe release operation). The nanostructure release operation is performed to remove the sacrificial layers 702 (e.g., the silicon germanium layers). This results in openings between the channel layers 174 (e.g., the areas around the channel layers 174). The sacrificial layers 702 may be removed through the spaces that were previously occupied by the dummy gate structures 706. The nanostructure release operation may include the use of an etch tool to perform an etch operation to remove the sacrificial layers 702 based on a difference in etch selectivity between the material of the sacrificial layers 702 and the material of the channel layers 174, and between the material of the sacrificial layers 702 and the material of the inner spacers 176b. The inner spacers 176b may function as etch stop layers in the etch operation to protect the source/drain regions 168 from being etched.

The replacement gate operation includes forming gate dielectric layers 170 and gate structures (e.g., replacement gate structures) 172 of the integrated circuit devices 114 in the openings between the source/drain regions 168 and between the inner spacers 176b. In particular, the gate dielectric layers 170 and the gate structures 172 fill the areas between and around the channel layers 174 that were previously occupied by the sacrificial layers 702 such that the gate structures 172 fully wrap around the channel layers 174 and surround the channel layers 174. This increases control of the channel layers 174, increases drive current for the integrated circuit devices 114, and/or reduces short channel effects (SCEs) for the integrated circuit devices 114, among other examples. The gate structures 172 may also fill in the spaces that were previously occupied by the dummy gate structures 706. Portions of a gate structure 172 are formed in between pairs of channel layers 174 in an alternating vertical arrangement. In other words, the semiconductor device 102 includes one or more vertical stacks of alternating channel layers 174 and portions of a gate structure 172.

As further shown in FIG. 7D, the source/drain contact structures 178 of the integrated circuit devices 114 may be formed through the dielectric layer 116. The source/drain contact structures 178 may be formed in recesses in the dielectric layer 116. In some implementations, a pattern in a photoresist layer is used to etch the dielectric layer 116 to form the recesses. In these implementations, a deposition tool may be used to form the photoresist layer on the dielectric layer 116. An exposure tool may be used to expose the photoresist layer to a radiation source to pattern the photoresist layer. A developer tool may be used to develop and remove portions of the photoresist layer to expose the pattern. An etch tool may be used to etch the dielectric layer 116 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 116 based on a pattern to form the recesses.

The source/drain contact structures 178 may be formed in the recesses such that the source/drain contact structures 178 land on the source/drain regions 168. A deposition tool may be used to deposit the material of the source/drain contact structures 178 in the recesses using a CVD technique, a PVD technique, an ALD technique, an electroplating technique, and/or another suitable deposition technique. The material of the source/drain contact structures 178 may be deposited in one or more deposition operations. In some implementations, a seed layer is first deposited, and the material of the source/drain contact structures 178 is deposited on the seed layer. In some implementations, one or more liner layers 180 are deposited in the recesses, and the source/drain contact structures 178 are deposited on the liner layer(s) 180. In some implementations, a planarization tool is used to perform a planarization operation (e.g., a chemical-mechanical planarization (CMP) operation) to planarize the source/drain contact structures 178 after the source/drain contact structures 178 are deposited such that the tops of the source/drain contact structures 178 are approximately co-planar with the top of the dielectric layer 116.

As shown in FIG. 7E, a first portion of the interconnect layer 108 of the semiconductor device 102 is formed above the device layer 106. One or more deposition tools are used to deposit alternating layers of ILD layers 118 and ESLs 120 in the first portion of the interconnect layer 108 of the semiconductor device 102. In this way, the ILD layers 118 and ESLs 120 may be arranged in the z-direction in the semiconductor device 102. One or more deposition tools may be used to deposit each of the ILD layers 118 and each of the ESLs 120 using a PVD technique, an ALD technique, a CVD technique, an oxidation technique, and/or another suitable deposition technique. In some implementations, a planarization tool may be used to planarize the ILD layers 118 and/or the ESLs 120 after the ILD layers 118 and/or the ESLs 120 are deposited.

As further shown in FIG. 7E, a deposition tool, an exposure tool, a developer tool, an etch tool, a planarization tool, a plating tool, and/or another semiconductor processing tool may be used to perform various operations to form the conductive structures 122 in the first portion of the interconnect layer 108 of the semiconductor device 102. In some implementations, the first portion of the interconnect layer 108 may be formed in a plurality of layers. For example, an ILD layer 118 and an ESL 120 may be formed (e.g., using one or more deposition tools and/or one or more planarization tools), recesses may be formed in and/or through the ILD layer 118 and the ESL 120 (e.g., using an exposure tool, a developer tool, and/or an etch tool), and a first layer (e.g., the M0 layer) of conductive structures 122 (e.g., of metallization structures) may be formed in the ILD layer 118 and the ESL 120 (e.g., using one or more deposition tools and/or one or more planarization tools). Another ILD layer 118 and another ESL 120 may be formed, and a second layer (e.g., the V0 layer) of conductive structures 122 (e.g., of interconnect structures) may be formed in the ILD layer 118 and the ESL 120. Additional layers of conductive structures 122 may be formed in the interconnect layer 108 a similar manner.

One or more deposition tools may be used to deposit the conductive structures 122 using a PVD technique, an ALD technique, a CVD technique, an electroplating technique (e.g., an electro-chemical plating technique), and/or another suitable deposition technique. In some implementations, a planarization tool may be used to planarize the conductive structures 122 after the conductive structures 122 are deposited.

As shown in FIG. 7F, a second portion of the interconnect layer 108 of the semiconductor device 102 may be formed above the first portion of the interconnect layer 108. The second portion of the interconnect layer 108 may include the ESLs 124, 128, 132, and 136, the ILD layers 126, 130, 134, and 138, the top vias 140 and 144, and the top metal layers 142 and 146. One or more deposition tools are used to deposit the ESLs 124, 128, 132, 136 and the ILD layers 126, 130, 134, 138 using a PVD technique, an ALD technique, a CVD technique, an oxidation technique, and/or another suitable deposition technique. In some implementations, a planarization tool may be used to planarize the ESLs 124, 128, 132, 136 and the ILD layers 126, 130, 134, 138.

As further shown in FIG. 7F, a deposition tool, an exposure tool, a developer tool, an etch tool, a planarization tool, a plating tool, and/or another semiconductor processing tool may be used to perform various operations to form the top vias 140, 144 and the top metal layers 142, 146 in the second portion of the interconnect layer 108 of the semiconductor device 102. In some implementations, the ESL 124 and the ILD layer 126 may be formed, recesses may be formed in and/or through the ESL 124 and the ILD layer 126 (e.g., using an exposure tool, a developer tool, and/or an etch tool), and the top vias 140 may be formed in the recesses (e.g., using one or more deposition tools and/or one or more planarization tools). In some implementations, the ESL 128 and the ILD layer 130 may be formed, recesses may be formed in and/or through the ESL 128 and the ILD layer 130 (e.g., using an exposure tool, a developer tool, and/or an etch tool), and the top metal layers 142 may be formed in the recesses (e.g., using one or more deposition tools and/or one or more planarization tools). In some implementations, the ESL 132 and the ILD layer 134 may be formed, recesses may be formed in and/or through the ESL 132 and the ILD layer 134 (e.g., using an exposure tool, a developer tool, and/or an etch tool), and the top vias 144 may be formed in the recesses (e.g., using one or more deposition tools and/or one or more planarization tools). In some implementations, the ESL 136 and the ILD layer 138 may be formed, recesses may be formed in and/or through the ESL 136 and the ILD layer 138 (e.g., using an exposure tool, a developer tool, and/or an etch tool), and the top metal layers 146 may be formed in the recesses (e.g., using one or more deposition tools and/or one or more planarization tools).

One or more deposition tools may be used to deposit the top vias 140, 144 and the top metal layers 142, 146 using a PVD technique, an ALD technique, a CVD technique, an electroplating technique (e.g., an electro-chemical plating technique), and/or another suitable deposition technique. In some implementations, a planarization tool may be used to planarize the top vias 140, 144 and the top metal layers 142, 146 after the top vias 140, 144 and the top metal layers 142, 146 are deposited.

As shown in FIGS. 7G-7K, one or more test pads 162 may be formed above the top metal layer 146 in the semiconductor device 102. The test pad(s) 162 may be formed for subsequent testing of the semiconductor device 102.

As shown in FIG. 7G, the ESL 148 may be formed over the interconnect layer 108, including over the top metal layer 146 and the ILD layer 138. A deposition tool may be used to deposit the material of the ILD layer 138 using a CVD technique, an ALD technique, a PVD technique, an oxidation technique, and/or another suitable deposition technique. A planarization tool may be used to perform a planarization operation (e.g., a CMP operation) to planarize the ILD layer 138.

As further shown in FIG. 7G, the passivation layer 150 may be formed over and/or on the ESL 148. A deposition tool may be used to deposit the material of the passivation layer 150 using a CVD technique, an ALD technique, a PVD technique, an oxidation technique, and/or another suitable deposition technique. A planarization tool may be used to perform a planarization operation (e.g., a CMP operation) to planarize the passivation layer 150.

As shown in FIG. 7H, a recess 708 (or a plurality of recesses 708) may be formed in and/or through the passivation layer 150 and/or the ESL 148. The recess 708 may be formed over a metallization structure of the top metal layer 146 so that the top surface of the metallization structure is exposed in the recess 708.

In some implementations, a pattern in a photoresist layer is used to etch the ESL 148 and/or the passivation layer 150 to form the recess 708. In these implementations, a deposition tool may be used to form the photoresist layer on the passivation layer 150 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern.

An etch tool may be used to etch the ESL 148 and/or the passivation layer 150 based on the pattern to form the recess 708. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 708 based on a pattern.

In some implementations, a recess 708 is formed such that a width at the bottom of the recess 708 (corresponding to the dimension D4 in FIGS. 2A and 2B) is greater than a width of a top surface of an underlying metallization structure of the top metal layer 146 (corresponding to dimension D6 in FIGS. 2A and 2B).

In some implementations, a recess 708 is formed such that a width at the top of the recess 708 (corresponding to the dimension D3 in FIGS. 4A and 4B) and a width of a top surface of an underlying metallization structure of the top metal layer 146 (corresponding to dimension D6 in FIGS. 4A and 4B) are approximately equal.

In some implementations, a recess 708 is formed such that a width at the top of the recess 708 (corresponding to the dimension D3 in FIGS. 5A and 5B) is less than a width of a top surface of an underlying metallization structure of the top metal layer 146 (corresponding to dimension D6 in FIGS. 5A and 5B).

As shown in FIG. 7I, a barrier layer 164 of one or more test pads 162 may be conformally deposited over the passivation layer 150. The barrier layer 164 may also be conformally deposited on the sidewalls and the bottom surface of a recess 708. Thus, the barrier layer 164 may be deposited on the top surface of the metallization structure of the top metal layer 146 that is exposed in the recess 708. A deposition tool may be used to deposit the material of the barrier layer 164 using a conformal deposition technique such as CVD and/or ALD. Additionally and/or alternatively, another deposition technique such as PVD may be used to deposit the material of the barrier layer 164.

As shown in FIG. 7J, a layer 710 of electrically conductive material may be deposited over the barrier layer 164, including above the passivation layer 150 in the recess 708. The layer 710 of electrically conductive material may fill in the recess 708 such that the top surface of the layer 710 in the recess 708 is above the top surface of the passivation layer 150. In other words, the layer 710 fully fills in the recess 708, and excess material of the layer 710 may extend above the top surface of the passivation layer 150.

A deposition tool may be used to deposit the layer 710 of electrically conductive material using a deposition technique such as CVD, ALD, PVD, electroplating, and/or another suitable deposition technique. The electrically conductive material may include one or more metals, one or more metal alloys, and/or another type of electrically conductive material such as tungsten (W), cobalt (Co), ruthenium (Ru), titanium (Ti), aluminum (Al), copper (Cu), gold (Au), and/or a combination thereof, among other examples of electrically conductive materials.

As shown in FIG. 7K, a first planarization operation may be performed on the test pad(s) 162 to define the metal pads 166 of the test pad(s) 162. In particular, a planarization tool may be used to perform the first planarization operation (e.g., a first CMP operation) to planarize the layer 710 of electrically conductive material and the barrier layer 164 to remove excess material of the layer 710 and excess material of the barrier layer 164 that was formed over the passivation layer 150. The remaining portions of the barrier layer 164 and the remaining portions of the layer 710 in the recesses 708 may correspond to the test pads 162.

As further shown in FIG. 7K, after the first planarization operation, a test pad 162 may have a pre-test thickness indicated in FIG. 7K as a dimension D7. The pre-test thickness may be greater than a post-test thickness of the test pad 162 corresponding to the dimension D2 in FIG. 2A. The greater thickness for the pre-test thickness of the test pad 162 enables the test pad 162 to be re-planarized after testing is performed on the semiconductor device 102 at 608 so that imperfections formed in the test pad 162 due to testing can be removed. In some implementations, if the post-test thickness of the test pad 162 (e.g., the dimension D2) is to be in a range of approximately 1 angstrom to approximately 10,000 angstroms, the test pad 162 may be formed to a pre-test thickness (e.g., the dimension D7) that is greater than 10,000 angstroms and up to approximately 30,000 angstroms, among other examples. However, other values and ranges are within the scope of the present disclosure.

As shown in FIG. 7L, at 608, testing of the semiconductor device 102 may be performed. The testing may include applying one or more test probes 712 to the test pad(s) 162 formed in the semiconductor device 102. In some implementations, one or more test inputs (e.g., test signals, test voltages) may be applied through a test probe 712 to a test pad 162 to perform a CP test, a WAT, an EVS test, and/or another type of test. In some implementations, a measurement may be taken by applying a test probe 712 to measure an output (e.g., a voltage, a resistance, a current) at a test pad 162.

As further shown in FIG. 7L, the test probe 712 physically contacts the test pad 162, which causes the top surface of the test pad 162 to deform. The mechanical stress applied to the surface of the metal pad 166 of the test pad 162 may cause material of the metal pad 166 to become displaced, resulting in the deformation in the top surface of the test pad 162.

As shown in FIG. 7M, a second planarization operation of the test pad(s) 162 may be performed as part of 610 and after testing of the semiconductor device 102 at 608. The second planarization operation may be performed to remove probing marks from the test pad(s) 162 (e.g., to remove deformations in the top surfaces of the test pad(s) 162). In this way, the second planarization operation refinishes the top surfaces of the test pad(s) 162, making the top surfaces of the test pad(s) 162 substantially flat and planar again. The second planarization operation may be performed so that the probing marks do not interfere with subsequent processes, such as the formation of subsequent layers on the test pad(s) 162.

A planarization tool may be used to perform the second planarization operation, which may include a CMP operation and/or another suitable type of planarization operation. As shown in FIG. 7M, the second planarization operation removes material from the test pad(s) 162 (e.g., from the barrier layers 164 and from the metal pads 166 of the test pad(s) 162), resulting in a reduction in thickness of the test pad(s) 162 from the pre-test thickness (dimension D7) to the post-test thickness (dimension D2). Material may also be removed from the passivation layer 150 in the second planarization operation (which also reduces the thickness of the passivation layer 150) so that the top surface of the passivation layer 150 and the top surfaces of the test pad(s) 162 are approximately co-planar.

As shown in FIGS. 7N-7P, additional operations may be performed as part of 610, including forming the ESL 152, the dielectric layer 154, and the bonding dielectric layer 160, as shown in FIG. 7N. The ESL 152 may be deposited over and/or on the passivation layer 150, and over and/or on the test pad(s) 162. A deposition tool may be used to deposit the material of the ESL 152 using a CVD technique, an ALD technique, a PVD technique, an oxidation technique, and/or another suitable deposition technique. A planarization tool may be used to perform a planarization operation to planarize the ESL 152.

The dielectric layer 154 may be deposited over and/or on the ESL 152. A deposition tool may be used to deposit the material of the dielectric layer 154 using a CVD technique, an ALD technique, a PVD technique, an oxidation technique, and/or another suitable deposition technique. A planarization tool may be used to perform a planarization operation to planarize the dielectric layer 154.

The bonding dielectric layer 160 may be deposited over and/or on the dielectric layer 154. A deposition tool may be used to deposit the material of the bonding dielectric layer 160 using a CVD technique, an ALD technique, a PVD technique, an oxidation technique, and/or another suitable deposition technique. A planarization tool may be used to perform a planarization operation to planarize the bonding dielectric layer 160.

As shown in FIG. 7O, recesses 708 may be formed in and/or through the ESL 148, the passivation layer 150, the ESL 152, the dielectric layer 154, and/or the bonding dielectric layer 160. The recesses 708 may be formed above and/or over one or more metallization structures in the top metal layer 146. In some implementations, a recess 708 may be formed laterally adjacent to a test pad 162.

A recess 714 may include a dual damascene recess that includes a via portion 716 and a trench portion 718 above the via portion 716. In these implementations, the recess 714 may be formed by performing a dual damascene etching process to form the trench portion 718 above the via portion 716 in sequential operations. The via portions 716 of the recesses 714 may be located at a same vertical height (e.g., in the same layer) in the semiconductor device 102 as the test pad(s) 162, and the trench portions 718 may be located higher in the semiconductor device 102 than the test pad(s) 162 (e.g., in a layer above the test pad(s) 162).

For example, a via-first dual damascene process may be performed to form the recess 714. The via-first dual damascene process may include etching the ESL 148, the passivation layer 150, the ESL 152, the dielectric layer 154, and/or the bonding dielectric layer 160 to form the via portion 716 of the recess 714 in a first etch operation, and etching the ESL 152, the dielectric layer 154, and/or the bonding dielectric layer 160 to form the trench portion 718 of the recess 714 in a second etch operation after the first etch operation. In some implementations, a sacrificial plug may be formed in the via portion 716 between the first etch operation and the second etch operation so that the sacrificial plug protects the via portion 716 from additional etching during the second etch operation.

As another example, a trench-first dual damascene process may be performed to form the recess 714. The trench-first dual damascene process may include etching the ESL 152, the dielectric layer 154, and/or the bonding dielectric layer 160 to form the trench portion 718 of the recess 714 in a first etch operation, and etching the ESL 148, the passivation layer 150, the ESL 152, the dielectric layer 154, and/or the bonding dielectric layer 160 to form the via portion 716 of the recess 714 in a second etch operation after the first etch operation.

As shown in FIG. 7P, electrically conductive material may be deposited into the recesses 714 to form the bonding interconnects 156 and the bonding pads 158 in the recesses 714. In particular, the bonding interconnects 156 may be formed in the via portions 716 of the recesses 714, and the bonding pads 158 may be formed in the trench portions 718 of the recesses 714.

The electrically conductive material may include one or more metals, one or more metal alloys, and/or another type of electrically conductive material such as tungsten (W), cobalt (Co), ruthenium (Ru), titanium (Ti), aluminum (Al), copper (Cu), gold (Au), and/or a combination thereof, among other examples of electrically conductive materials.

A deposition tool may be used to deposit the electrically conductive material of the bonding interconnects 156 and of the bonding pads 158 using a CVD technique, an ALD technique, a PVD technique, an electroplating technique, and/or another suitable deposition technique. A deposition tool may be used to perform a planarization operation (e.g., a CMP operation) to planarize the bonding pads 158. In some implementations, a liner (e.g., a tantalum nitride (TaN) liner, a titanium nitride (TiN) liner) is first deposited in the recesses 708, and the bonding interconnects 156 and of the bonding pads 158 are deposited on the liner.

As indicated above, FIGS. 7A-7P are provided as an example. Other examples may differ from what is described with regard to FIGS. 7A-7P.

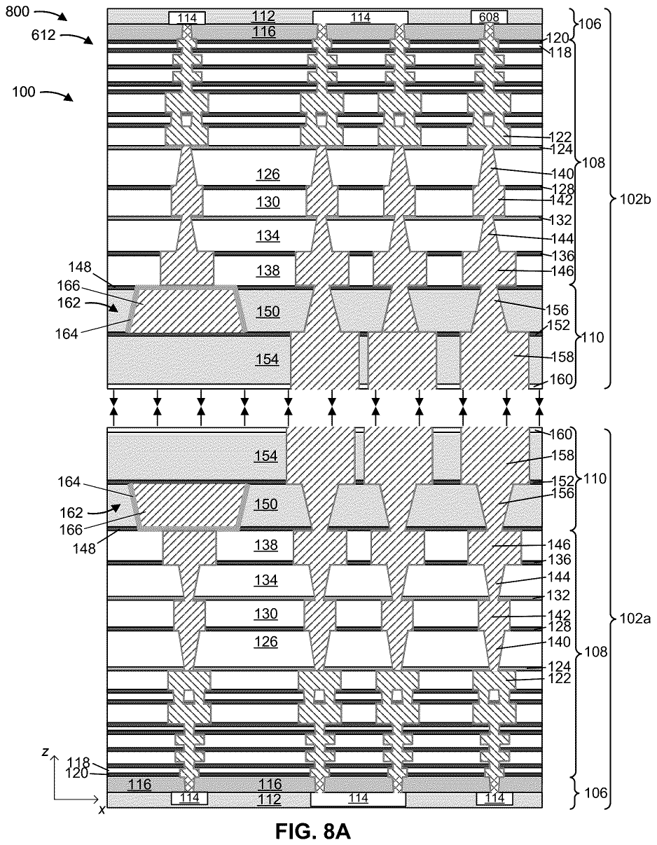

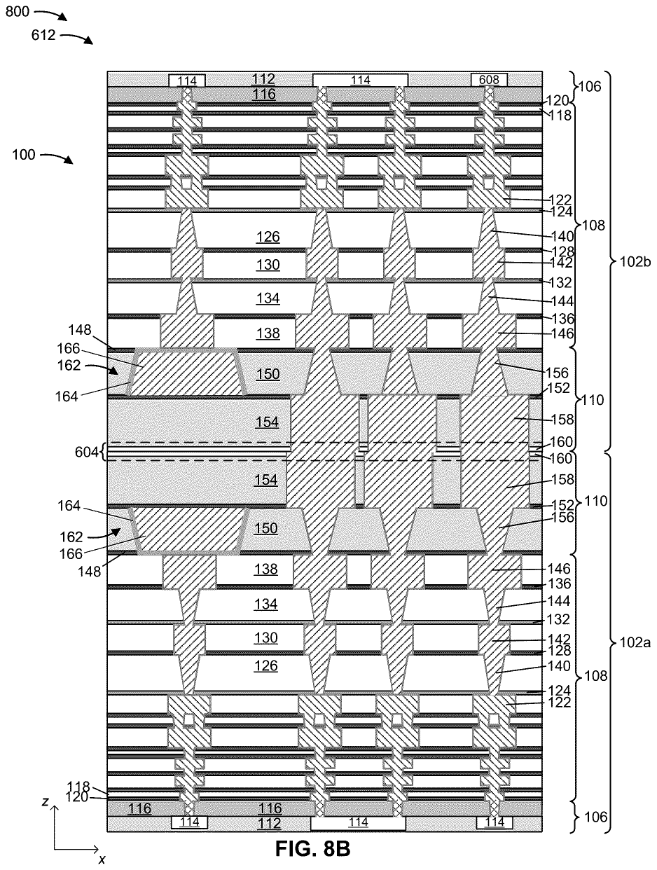

FIGS. 8A and 8B are diagrams of an example implementation 800 of forming a stacked semiconductor device 100 described herein. The example implementation 800 may include operations that are performed as part of the process illustrated in connection with FIG. 6, such as operations performed as part of 612, 614, 616, and/or 618, among other examples. In some implementations, one or more semiconductor processing tools, such as a bonding tool, may be used to perform one or more operations described in connection with FIGS. 8A and 8B.

As shown in FIGS. 8A and 8B, at 612, the semiconductor devices 102a and 102b may be bonded together at the bonding interface 104 to form the stacked semiconductor device 100. The bond between the semiconductor devices 102a and 102b may be formed by bonding the semiconductor wafers 602a and 602b together (e.g., wafer-to-wafer bonding), by bonding dies together (die-to-die bonding), and/or by bonding a die to a wafer (e.g., die-to-wafer bonding), among other example bonding configurations.

A bonding tool may be used to perform a bonding operation to bond the semiconductor devices 102a and 102b by forming metal-to-metal bonds between the bonding pads 158 of the semiconductor device 102b and the bonding pads 158 of the semiconductor device 102a, and/or dielectric-to-dielectric bonds between the bonding dielectric layer 160 of the semiconductor device 102a and the bonding dielectric layer 160 of the semiconductor device 102b.

In some implementations, the semiconductor devices 102a and 102b are bonded such that the test pad(s) 162 of the semiconductor device 102a and the test pad(s) 162 of the semiconductor device 102b are facing each other and separated by one or more dielectric layers. For example, the test pad(s) 162 of the semiconductor device 102a and the test pad(s) 162 of the semiconductor device 102b may be spaced apart by the ESLs 152, the dielectric layers 154, and/or the bonding dielectric layers 160 of the semiconductor devices 102a and 102b, without intervening bonding interconnects 156 and/or intervening bonding pads 158 between the test pad(s) 162 of the semiconductor device 102a and the test pad(s) 162 of the semiconductor device 102b.

As indicated above, FIGS. 8A and 8B are provided as an example. Other examples may differ from what is described with regard to FIGS. 8A and 8B.

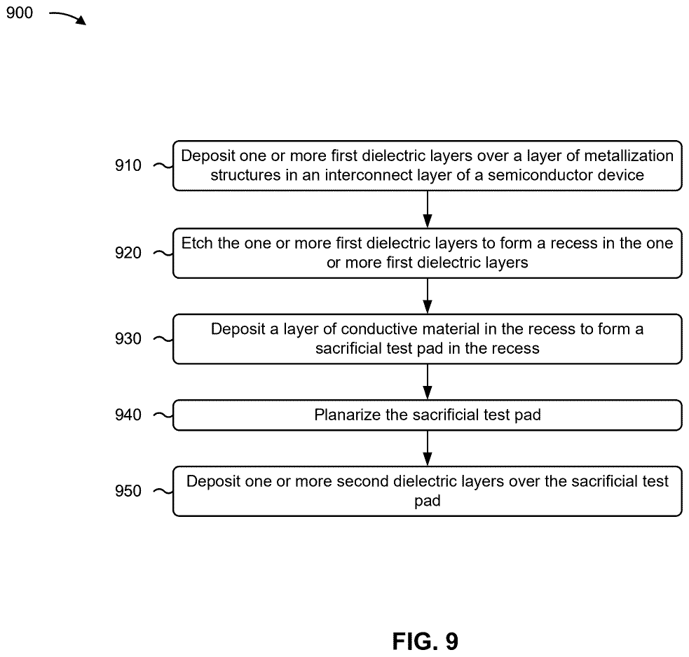

FIG. 9 is a flowchart of an example process 900 associated with forming a semiconductor device described herein. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 9, process 900 may include depositing one or more first dielectric layers over a layer of metallization structures in an interconnect layer of a semiconductor device (block 910). For example, one or more semiconductor processing tools may be used to deposit one or more first dielectric layers (e.g., e.g., an ESL 148, a passivation layer 150) over a layer of metallization structures (e.g., top metal layer 146) in an interconnect layer (e.g., an interconnect layer 108) of a semiconductor device (e.g., a semiconductor device 102, a semiconductor device 102a, a semiconductor device 102b), as described herein.

As further shown in FIG. 9, process 900 may include etching the one or more first dielectric layers to form a recess in the one or more first dielectric layers (block 920). For example, one or more semiconductor processing tools may be used to etch the one or more first dielectric layers to form a recess (e.g., a recess 708) in the one or more first dielectric layers, as described herein.

As further shown in FIG. 9, process 900 may include depositing a layer of conductive material in the recess to form a sacrificial test pad in the recess (block 930). For example, one or more semiconductor processing tools may be used to deposit a layer (e.g., a layer 710) of conductive material in the recess to form a sacrificial test pad (e.g., a test pad 162) in the recess, as described herein. In some implementations, the sacrificial test pad is formed over a metallization structure (e.g., a metallization structure of the top metal layer 146) of the metallization structures.

As further shown in FIG. 9, process 900 may include planarizing the sacrificial test pad (block 940). For example, one or more semiconductor processing tools may be used to planarize the sacrificial test pad, as described herein.

As further shown in FIG. 9, process 900 may include depositing one or more second dielectric layers over the sacrificial test pad (block 950). For example, one or more semiconductor processing tools may be used to deposit one or more second dielectric layers (e.g., an ESL 152, a dielectric layer 154, a bonding dielectric layer 160) over the sacrificial test pad, as described herein.

Process 900 may include additional implementations, such as any single implementation or any combination of implementations described below and/or in connection with one or more other processes described elsewhere herein.

In a first implementation, the layer of conductive material and the layer of metallization structures includes copper (Cu).

In a second implementation, alone or in combination with the first implementation, process 900 includes depositing a conformal barrier layer (e.g., a barrier layer 164) in the recess, where depositing the layer of conductive material in the recess to form the sacrificial test pad includes depositing the layer of conductive material on the conformal barrier layer in the recess to form the sacrificial test pad.

In a third implementation, alone or in combination with one or more of the first and second implementations, process 900 includes etching the one or more second dielectric layers to form a dual damascene recess (e.g., a recess 708) in the one or more second dielectric layers, and depositing another layer of conductive material in the dual damascene recess to form a bonding interconnect (e.g., a bonding interconnect 156) and a bonding pad (e.g., a bonding pad 158) in the dual damascene recess, where a bottom surface (e.g., a bottom surface 204) of the bonding pad extends into at least one of the one or more first dielectric layers.

In a fourth implementation, alone or in combination with one or more of the first through third implementations, a top surface of the sacrificial test pad is higher in the semiconductor device than the bottom surface of the bonding pad.

In a fifth implementation, alone or in combination with one or more of the first through fourth implementations, process 900 includes etching the one or more second dielectric layers to form a dual damascene recess (e.g., a recess 708) in the one or more second dielectric layers, and depositing another layer of conductive material in the dual damascene recess to form a bonding interconnect (e.g., a bonding interconnect 156) and a bonding pad (e.g., a bonding pad 158) in the dual damascene recess, where a bottom surface (e.g., a bottom surface 204) of the bonding pad and a top surface (e.g., a top surface 202) of the sacrificial test pad are approximately co-planar.

In a sixth implementation, alone or in combination with one or more of the first through fifth implementations, a thickness (e.g., a dimension D2) of the sacrificial test pad, after planarizing the sacrificial test pad, is greater than approximately 1 angstrom and less than approximately 10,000 angstroms.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

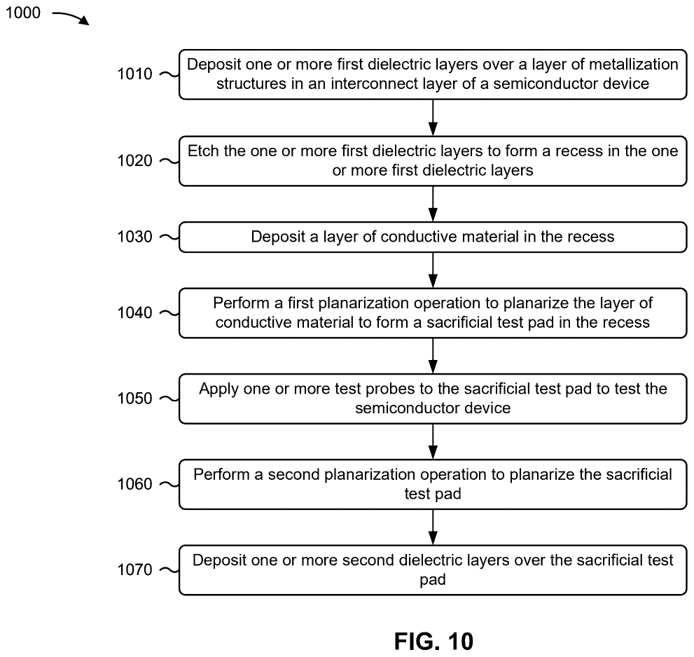

FIG. 10 is a flowchart of an example process 1000 associated with forming a semiconductor device described herein. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a bonding tool, a wafer/die transport tool, and/or another type of semiconductor processing tool.

As shown in FIG. 10, process 1000 may include depositing one or more first dielectric layers over a layer of metallization structures in an interconnect layer of a semiconductor device (block 1010). For example, one or more semiconductor processing tools may be used to deposit one or more first dielectric layers (e.g., an ESL 148, a passivation layer 150) over a layer of metallization structures (e.g., a top metal layer 146) in an interconnect layer (e.g., an interconnect layer 108) of a semiconductor device (e.g., a semiconductor device 102, a semiconductor device 102a, a semiconductor device 102b), as described herein.

As further shown in FIG. 10, process 1000 may include etching the one or more first dielectric layers to form a recess in the one or more first dielectric layers (block 1020). For example, one or more semiconductor processing tools may be used to etch the one or more first dielectric layers to form a recess (e.g., a recess 708) in the one or more first dielectric layers, as described herein.

As further shown in FIG. 10, process 1000 may include depositing a layer of conductive material in the recess (block 1030). For example, one or more semiconductor processing tools may be used to deposit a layer (e.g., a layer 710) of conductive material in the recess, as described herein.

As further shown in FIG. 10, process 1000 may include performing a first planarization operation to planarize the layer of conductive material to form a sacrificial test pad in the recess (block 1040). For example, one or more semiconductor processing tools may be used to perform a first planarization operation to planarize the layer of conductive material to form a sacrificial test pad (e.g., a test pad 162) in the recess, as described herein. In some implementations, the sacrificial test pad is formed over a metallization structure (e.g., a metallization structure of the top metal layer 146) of the metallization structures.

As further shown in FIG. 10, process 1000 may include applying one or more test probes to the sacrificial test pad to test the semiconductor device (block 1050). For example, one or more semiconductor processing tools may be used to apply one or more test probes (e.g., one or more test probes 712) to the sacrificial test pad to test the semiconductor device, as described herein.

As further shown in FIG. 10, process 1000 may include performing a second planarization operation to planarize the sacrificial test pad (block 1060). For example, one or more semiconductor processing tools may be used to perform a second planarization operation to planarize the sacrificial test pad, as described herein.

As further shown in FIG. 10, process 1000 may include depositing one or more second dielectric layers over the sacrificial test pad (block 1070). For example, one or more semiconductor processing tools may be used to deposit one or more second dielectric layers (e.g., an ESL 152, a dielectric layer 154, a bonding dielectric layer 160) over the sacrificial test pad, as described herein.

Process 1000 may include additional implementations, such as any single implementation or any combination of implementations described below and/or in connection with one or more other processes described elsewhere herein.

In a first implementation, performing the second planarization operation includes performing the planarization operation after applying the one or more test probes to the sacrificial test pad to test the semiconductor device.

In a second implementation, alone or in combination with the first implementation, process 1000 includes bonding the semiconductor device to another semiconductor device (e.g., a semiconductor device 102, a semiconductor device 102a, a semiconductor device 102b) to form a stacked semiconductor device (e.g., a stacked semiconductor device 100), where the semiconductor device and the other semiconductor device are stacked and vertically arranged in the stacked semiconductor device.

In a third implementation, alone or in combination with one or more of the first and second implementations, process 1000 includes etching the one or more second dielectric layers to form a dual damascene recess (e.g., a recess 708) in the one or more second dielectric layers, and depositing another layer of conductive material in the dual damascene recess to form a bonding interconnect (e.g., a bonding interconnect 156) and a bonding pad (e.g., bonding pad 158) in the dual damascene recess, where bonding the semiconductor device to the other semiconductor device includes bonding the bonding pad of the semiconductor device to another bonding pad (e.g., a bonding pad 158) of the other semiconductor device to form a metal-to-metal bond.

In a fourth implementation, alone or in combination with one or more of the first through third implementations, bonding the semiconductor device to the other semiconductor device includes bonding at least one of the one or more second dielectric layers of the semiconductor device to a fourth dielectric layer of the other semiconductor device to form a dielectric-to-dielectric bond.

In a fifth implementation, alone or in combination with one or more of the first through fourth implementations, the sacrificial test pad is spaced apart from the other semiconductor device by the one or more second dielectric layers.

In a sixth implementation, alone or in combination with one or more of the first through fifth implementations, the layer of conductive material and the other layer of conductive material each comprise copper (Cu).

In a seventh implementation, alone or in combination with one or more of the first through sixth implementations, process 1000 includes forming a barrier layer (e.g., a barrier layer 164) in the recess, where depositing the layer of conductive material in the recess includes depositing the layer of conductive material on the barrier layer in the recess.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, sacrificial test pads are formed in a semiconductor device and used for testing operations for the semiconductor device prior to bonding the semiconductor device with another semiconductor device to form a stacked semiconductor device. The sacrificial test pads may be formed in the interconnect layer (e.g., the back end of the semiconductor device), and may be formed of materials such as copper (Cu) that enable the sacrificial test pads to be integrated into the manufacturing processes for the metallization of the interconnect layer.

To prevent or reduce the likelihood of the uneven topographies of the sacrificial test pads from degrading bonding performance of the semiconductor devices, a planarization operation may be performed to planarize the surfaces of the sacrificial test pads. The sacrificial test pads may be subsequently covered by a dielectric layer to reduce the likelihood of oxidation of the sacrificial test pads. Retaining the sacrificial test pads, in turn, reduces the likelihood of oxidation of metallization structures under the sacrificial test pads.

As described in greater detail above, some implementations described herein provide a method. The method includes depositing one or more first dielectric layers over a layer of metallization structures in an interconnect layer of a semiconductor device. The method includes etching the one or more first dielectric layers to form a recess in the one or more first dielectric layers. The method includes depositing a layer of conductive material in the recess to form a sacrificial test pad in the recess, where the sacrificial test pad is formed over a metallization structure of the metallization structures. The method includes planarizing the sacrificial test pad. The method includes depositing one or more second dielectric layers over the sacrificial test pad.

As described in greater detail above, some implementations described herein provide a method. The method includes depositing one or more first dielectric layers over a layer of metallization structures in an interconnect layer of a semiconductor device. The method includes etching the one or more first dielectric layers to form a recess in the one or more first dielectric layers. The method includes depositing a layer of conductive material in the recess. The method includes performing a first planarization operation to planarize the layer of conductive material to form a sacrificial test pad in the recess, where the sacrificial test pad is formed over a metallization structure of the metallization structures. The method includes applying one or more test probes to the sacrificial test pad to test the semiconductor device. The method includes performing a second planarization operation to planarize the sacrificial test pad. The method includes depositing one or more second dielectric layers over the sacrificial test pad.

As described in greater detail above, some implementations described herein provide a semiconductor device. The semiconductor device includes a device layer. The semiconductor device includes a plurality of transistors in the device layer. At least one of the plurality of transistors includes a channel layer, a gate structure adjacent to at least three sides of the channel layer, and a gate dielectric layer between the channel layer and the gate structure. The semiconductor device includes an interconnect layer over the plurality of transistors. The interconnect layer includes a plurality of dielectric layers a plurality of layers of metallization structures disposed in the plurality of dielectric layers, where the plurality of layers of metallization structures are spaced apart from one another by the plurality of dielectric layers, and where a dielectric constant of the gate dielectric layer is greater than a dielectric constant of the plurality of dielectric layers a passivation layer above the plurality of layers of metallization structures a bonding interconnect in the passivation layer a copper (Cu) test pad in the passivation layer.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
depositing one or more first dielectric layers over a layer of metallization structures in an interconnect layer of a semiconductor device;
etching the one or more first dielectric layers to form a recess in the one or more first dielectric layers;
depositing a layer of conductive material in the recess to form a sacrificial test pad in the recess,
wherein the sacrificial test pad is formed over a metallization structure of the metallization structures;
planarizing the sacrificial test pad; and
depositing one or more second dielectric layers over the sacrificial test pad.

2. The method of claim 1, wherein the layer of conductive material and the layer of metallization structures comprise copper (Cu).

3. The method of claim 1, further comprising:
depositing a conformal barrier layer in the recess,
wherein depositing the layer of conductive material in the recess to form the sacrificial test pad comprises:
depositing the layer of conductive material on the conformal barrier layer in the recess to form the sacrificial test pad.

4. The method of claim 3, further comprising:
etching the one or more second dielectric layers to form a dual damascene recess in the one or more second dielectric layers; and
depositing another layer of conductive material in the dual damascene recess to form a bonding interconnect and a bonding pad in the dual damascene recess,
wherein a bottom surface of the bonding pad extends into at least one of the one or more first dielectric layers.

5. The method of claim 4, wherein a top surface of the sacrificial test pad is higher in the semiconductor device than the bottom surface of the bonding pad.

6. The method of claim 1, further comprising:
etching the one or more second dielectric layers to form a dual damascene recess in the one or more second dielectric layers; and
depositing another layer of conductive material in the dual damascene recess to form a bonding interconnect and a bonding pad in the dual damascene recess,
wherein a bottom surface of the bonding pad and a top surface of the sacrificial test pad are approximately co-planar.

7. The method of claim 1, wherein a thickness of the sacrificial test pad, after planarizing the sacrificial test pad, is greater than approximately 1 angstrom and less than approximately 10,000 angstroms.

8. A method, comprising:
depositing one or more first dielectric layers over a layer of metallization structures in an interconnect layer of a semiconductor device;
etching the one or more first dielectric layers to form a recess in the one or more first dielectric layers;
depositing a layer of conductive material in the recess;
performing a first planarization operation to planarize the layer of conductive material to form a sacrificial test pad in the recess,
wherein the sacrificial test pad is formed over a metallization structure of the metallization structures;
applying one or more test probes to the sacrificial test pad to test the semiconductor device;
performing a second planarization operation to planarize the sacrificial test pad; and
depositing one or more second dielectric layers over the sacrificial test pad.

9. The method of claim 8, wherein performing the second planarization operation comprises:
performing the planarization operation after applying the one or more test probes to the sacrificial test pad to test the semiconductor device.

10. The method of claim 8, further comprising:
bonding the semiconductor device to another semiconductor device to form a stacked semiconductor device,
wherein the semiconductor device and the other semiconductor device are stacked and vertically arranged in the stacked semiconductor device.

11. The method of claim 10, further comprising:
etching the one or more second dielectric layers to form a dual damascene recess in the one or more second dielectric layers; and
depositing another layer of conductive material in the dual damascene recess to form a bonding interconnect and a bonding pad in the dual damascene recess,
wherein bonding the semiconductor device to the other semiconductor device comprises:
bonding the bonding pad of the semiconductor device to another bonding pad of the other semiconductor device to form a metal-to-metal bond.

12. The method of claim 11, wherein bonding the semiconductor device to the other semiconductor device comprises:
bonding at least one of the one or more second dielectric layers of the semiconductor device to a fourth dielectric layer of the other semiconductor device to form a dielectric-to-dielectric bond.

13. The method of claim 11, wherein the sacrificial test pad is spaced apart from the other semiconductor device by the one or more second dielectric layers.

14. The method of claim 13, wherein the layer of conductive material and the other layer of conductive material each comprise copper (Cu).

15. The method of claim 8, further comprising:
forming a barrier layer in the recess,
wherein depositing the layer of conductive material in the recess comprises:
depositing the layer of conductive material on the barrier layer in the recess.

16. A semiconductor device, comprising:
a device layer;
a plurality of transistors in the device layer,
wherein at least one of the plurality of transistors comprises:
a channel layer;
a gate structure adjacent to at least three sides of the channel layer; and
a gate dielectric layer between the channel layer and the gate structure;
an interconnect layer, over the plurality of transistors, comprising:
a plurality of dielectric layers;
a plurality of layers of metallization structures disposed in the plurality of dielectric layers,
wherein the plurality of layers of metallization structures are spaced apart from one another by the plurality of dielectric layers, and
wherein a dielectric constant of the gate dielectric layer is greater than a dielectric constant of the plurality of dielectric layers;
a passivation layer above the plurality of layers of metallization structures;
a bonding interconnect in the passivation layer; and
a copper (Cu) test pad in the passivation layer.

17. The semiconductor device of claim 16, further comprising:
a barrier layer between the copper test pad and the passivation layer,
wherein the dielectric constant of the gate dielectric layer is greater than a dielectric constant of the barrier layer.

18. The semiconductor device of claim 16, wherein the copper test pad is over a metallization structure of the plurality of layers of metallization structures; and
wherein a width of the copper test pad is less than a width of the metallization structure.

19. The semiconductor device of claim 16, wherein the copper test pad is over a metallization structure of the plurality of layers of metallization structures; and
wherein a width of the copper test pad and a width of the metallization structure are approximately a same width.

20. The semiconductor device of claim 16, wherein the copper test pad is over a metallization structure of the plurality of layers of metallization structures; and
wherein a width of the copper test pad is greater than a width of the metallization structure.
